(19) United States
(12) Patent Application Publication
(10) Pub. No.: US 2026/0287656 A1
(43) Pub. Date: Sep. 24, 2026

(54) System for Directional Scan Access and Method for Directional Scan Testing Thereof

(71) Applicants: Hiroyuki Iwata, Hsinchu (TW); Sandeep Kumar Goel, Hsinchu (TW); Ankita Patidar, Hsinchu (TW); Fumiaki Takashima, Hsinchu (TW)

(72) Inventors: Hiroyuki Iwata, Hsinchu (TW); Sandeep Kumar Goel, Hsinchu (TW); Ankita Patidar, Hsinchu (TW); Fumiaki Takashima, Hsinchu (TW)

(21) Appl. No.: 19/264,071

(22) Filed: Jul. 9, 2025

Related U.S. Application Data
(60) Provisional application No. 63/773,570, filed on Mar. 18, 2025.
(60) Provisional application No. 63/781,600, filed on Apr. 1, 2025.

(51) Int. Cl. G01R 31/3185

(52) U.S. Cl. CPC G01R 31/318552

(57) ABSTRACT

A semiconductor system includes a plurality of dies arranged on a substrate and each including a core, a first multiplexer, a clock multiplexer, and a plurality of output circuits. The core is performs scan test operations. The first multiplexer receives scan data and control signals from at least one neighboring die and provides the scan data and control signals to the core. The clock multiplexer receives scan clock signals from at least one neighboring die and provides a selected scan clock signal to the core. Each output circuit includes an output multiplexer and a pipeline flip-flop and transmits scan data and control signals from the core to a neighboring die. The output multiplexer is coupled to the core. The pipeline flip-flop is coupled to the output multiplexer.

### CROSS-REFERENCE TO RELATED APPLICATION

The present application claims priority to U.S. Provisional Application Nos. 63/773,570, filed Mar. 18, 2025, and 63/781,600, filed Apr. 1, 2025, the contents of both are incorporated by reference herein in their entirety.

### BACKGROUND

A system-on-wafer (SoW) may, for example, refer to an integration approach in which system-on-chips (SoCs) or dies are arranged and interconnected on a common substrate. Each SoC may include processing, memory, and interface logic to support functional tasks. This architecture may enable high-density integration, low-latency inter-die communication, and increased interconnect bandwidth, while offering improved power efficiency. Such characteristics can make SoW architectures well-suited for compute-intensive applications such as artificial intelligence, machine learning, and high-performance computing.

Because of the complexity and scale of certain SoW configurations, testing may be performed to ensure functionality and reliability. Scan testing techniques can be used to verify electrical performance, detect structural faults, and identify possible defects before the SoCs are deployed in system operation. These tests may help ensure that each component functions as intended, both individually and in coordination with neighboring dies.

### BRIEF DESCRIPTION OF THE DRAWINGS

Aspects of the present disclosure are best understood from the following detailed description when read with the accompanying figures:

FIG. 1 is a schematic diagram illustrating an exemplary device in accordance with various embodiments of the present disclosure;

FIG. 2 is a schematic diagram illustrating an exemplary omnidirectional test interface implemented in a system-on-chip (SoC) in accordance with various embodiments of the present disclosure;

FIG. 3 is a schematic diagram illustrating an exemplary omnidirectional test access structure in a SoC or system-on-wafer (SoW) in accordance with various embodiments of the present disclosure;

FIG. 4 is a schematic diagram illustrating a direction switching structure for two directions in accordance with various embodiments of the present disclosure;

FIG. 5 is a schematic diagram illustrating an exemplary omnidirectional TAP structure in a SoW in accordance with various embodiments of the present disclosure;

FIG. 6 is a schematic diagram illustrating another exemplary TAP access structure in a SoW in accordance with various embodiments of the present disclosure;

FIG. 7 is a schematic diagram illustrating an exemplary scan data access structure across multiple dies in a SoC or SoW in accordance with various embodiments of the present disclosure;

FIG. 8 is a schematic diagram illustrating another exemplary scan data access structure across multiple dies in a SoC or SoW in accordance with various embodiments of the present disclosure;

FIG. 9 is a schematic diagram illustrating another exemplary omnidirectional TAP access structure across multiple dies in a SoC or SoW in accordance with various embodiments of the present disclosure;

FIG. 10 is a schematic diagram illustrating another exemplary omnidirectional test access and scan signal routing structure within a die of a SoC or SoW in accordance with various embodiments of the present disclosure;

FIG. 11 is a schematic diagram illustrating another exemplary scan signal routing structure for a die in a SoC or SoW in accordance with various embodiments of the present disclosure;

FIG. 12 is a schematic diagram illustrating another exemplary distributed TAP routing architecture across multiple dies in a SoC or SoW in accordance with various embodiments of the present disclosure;

FIG. 13 is a schematic diagram illustrating an alternative two-directional TAP access structure in a die of a SoC or SoW in accordance with various embodiments of the present disclosure;

FIG. 14 is a schematic diagram illustrating another exemplary two-directional TAP switching structure including PFFs in a SoC or SoW in accordance with various embodiments of the present disclosure;

FIG. 15 is a schematic diagram illustrating another exemplary omnidirectional TAP access structure utilizing direction enable signals in accordance with various embodiments of the present disclosure;

FIG. 16 is a schematic diagram illustrating another exemplary test access structure across multiple dies in a SoC or SoW in accordance with various embodiments of the present disclosure;

FIG. 17 is a schematic diagram illustrating a simplified scan data routing structure across multiple dies in a SoC or SoW in accordance with various embodiments of the present disclosure;

FIG. 18 is a timing diagram illustrating scan clock signal propagation in a roundtrip scan configuration within a SoW in accordance with various embodiments of the present disclosure;

FIG. 19 is a schematic diagram illustrating another exemplary test access structure in a SoC or SoW in accordance with various embodiments of the present disclosure;

FIG. 20A is a schematic diagram illustrating an exemplary unidirectional scan access structure across multiple dies in a SoC or SoW in accordance with various embodiments of the present disclosure;

FIG. 20B is a schematic diagram illustrating another exemplary unidirectional scan access structure across multiple dies in a SoC or SoW with reversed clock direction in accordance with various embodiments of the present disclosure;

FIG. 21A is a timing diagram illustrating an example of inter-die scan clock skew accumulation in a SoW in accordance with various embodiments of the present disclosure;

FIG. 21B is a timing diagram illustrating another exemplary scan clock selection configuration in a SoW that reduces skew in accordance with various embodiments of the present disclosure;

FIG. 22 is a schematic diagram illustrating an exemplary fault diagnosis system for identifying scan path faults in a SoW environment in accordance with various embodiments of the present disclosure;

FIG. 23 is a timing diagram illustrating an exemplary initialization sequence for TAP and scan path selection in a SoC or SoW according to various embodiments of the present disclosure;

FIG. 24 is a flowchart illustrating exemplary operations of a method of in accordance with various embodiments of the present disclosure; and

FIG. 25 is a flowchart illustrating exemplary operations of a method in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underneath,” “below,” “lower,” “above,” “on,” “top,” “bottom” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. The apparatus may be otherwise oriented (rotated 90 degrees or at other orientations) and the spatially relative descriptors used herein may likewise be interpreted accordingly.

As introduced above, a system-on-wafer (SoW) integrates one or more system-on-chips (SoCs) onto a common substrate to achieve system-level functionality. Each SoC may include processing logic, memory, and input/output (I/O) circuitry to support a range of computational or control functions. In such arrangements, each SoC may undergo scan-based testing both individually and as part of an interconnected SoW. To facilitate these tests, test access structures may be included within each SoC to support signal routing, scan data propagation, and local control.

However, the layout and operation of test interfaces across dies on a SoW may be limited by directional signal paths. If test signals can propagate only in one direction (e.g., left to right or top to bottom), some dies may become inaccessible due to faults or routing constraints. Variations in die orientation or placement may also reduce interface compatibility, limiting reuse and scalability. These factors can reduce design flexibility and complicate scan path planning.

Systems and methods as described in certain examples herein address these limitations by enabling test access to each SoC from multiple directions. Through the use of omnidirectional test interfaces, scan multiplexers, direction control logic, and rerouting mechanisms, each SoC can receive and transmit test signals in more than one direction. This approach may support broader test coverage, enhanced compatibility across dies, and more robust integration across a SoW, even under constrained pin or interconnect conditions. Various embodiments described below illustrate circuit-level implementations, scan signal routing configurations, and operational modes, including normal scan, rerouting, and roundtrip test access.

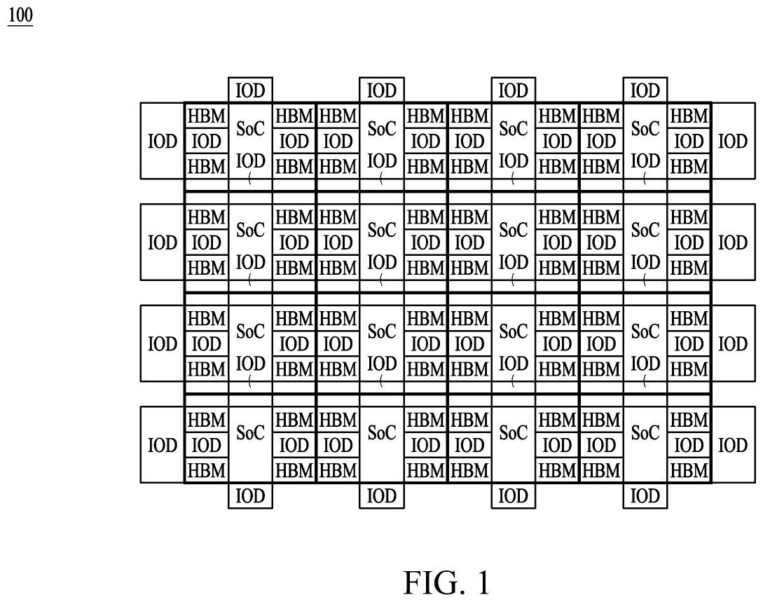

FIG. 1 is a schematic diagram illustrating an exemplary device in accordance with various embodiments of the present disclosure. As shown in FIG. 1, the example system, e.g., system-on-wafer (SoW), includes a plurality of system-on-chips (SoCs), a plurality of high-bandwidth memory (HBM) dies, and a plurality of input/output dies (IODs). The SoCs (or dies) are arranged in an array of rows and columns and each SoC is surrounded by HBMs and IODs. The HBMs support high-capacity, high-throughput memory access, while the IODs facilitate inter-SoC communication. This arrangement may be designed to meet the increasing performance and bandwidth demands of artificial intelligence (AI) and machine learning workloads.

In certain embodiments, each HBM die is disposed at a respective corner of its corresponding SoC, ensuring high local memory bandwidth. The SoW configuration enables each SoC to be paired with more than four HBMs, supporting memory-intensive applications. Each SoC is also coupled to neighboring IODs, providing chip-to-chip signaling paths with low latency and energy consumption. For example, the inter-SoC latency can be less than about 30 ns and energy efficiency can be better than about 2 pJ/bit, which is significantly more efficient. As a result, overall system performance can be increased and power consumption reduced.

The SoW architecture supports both scalability and modularity. A large number of compute nodes (SoCs) can operate in parallel across the wafer and the layout supports efficient test integration. Each SoC may include a test access structure that supports both single-die testing during wafer sort and system-level testing when the SoC is mounted as part of the SoW. The test access structure includes omnidirectional interfaces configured to receive and transmit test signals (e.g., TAP signals or scan data) from multiple directions, such as left, right, up, down, top, or bottom. The test interface of each SoC is accessed only from adjacent SoCs, enabling a distributed and low-pin-count test access strategy.

To facilitate this strategy, test signals may traverse configurable routes across the SoW. For example, the test access path can be freely defined depending on the SoC arrangement and if one SoC becomes unavailable due to a defect or routing fault, the path may be rerouted dynamically through other SoCs. This enables a plug-and-play model in which compatible SoCs can be replaced, rearranged, or retested without changes to the overall test infrastructure. Minimal test interface pins are required between SoCs, making this architecture suitable for dense, large-scale wafer integration with scalable test capabilities.

In one example of a normal test operation, a test access port (TAP) signal is injected into the leftmost SoC. The TAP signal is received and interpreted by the local TAP controller, and the scan test pattern is forwarded into the core for execution. After scan shifting through the core, the test response is routed outward to the neighboring SoC through a secondary TAP (STAP) controller in the right direction. This directional test propagation continues across the SoC chain, enabling comprehensive scan coverage of the system.

In a rerouting scenario, if one of the SoCs in the scan path becomes inactive or unavailable due to a fault, the system may update its test direction control to bypass the faulty die. For instance, the test signals may be redirected upward and then around the inactive die using alternative STAP paths. The flexibility in direction control enables continued test coverage even in degraded conditions.

In a localized test mode, a single SoC may be tested individually by receiving test signals from one neighboring SoC and collecting the result through another. This enables parallel testing of multiple SoCs, reducing overall test time. The omnidirectional interface allows each SoC to support loop-in/loop-out test strategies using adjacent SoCs, eliminating the need for probing the SoC or connecting it to external equipment.

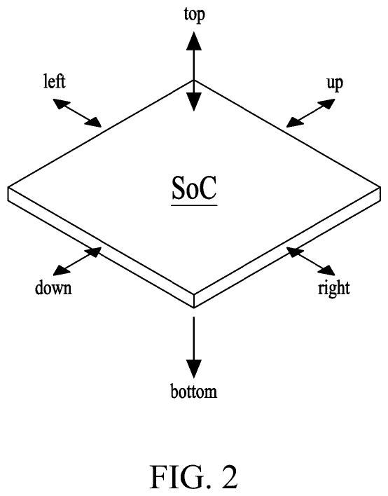

FIG. 2 is a schematic diagram illustrating an exemplary omnidirectional test interface implemented in a SoC in accordance with various embodiments of the present disclosure. As shown in FIG. 2, the example SoC (or die) is configured to transmit and receive test signals from six directions: left, right, up, down, top, and bottom. This omnidirectional test access capability enables each SoC to participate in test operations through any of its neighboring dies, whether arranged in a planar layout or a stacked 3D configuration.

The omnidirectional interface supports flexible test signal routing across a system-on-wafer (SoW) or multi-die package. In particular, this structure allows test signals such as TAP commands or scan data to enter the SoC/die from one direction and exit through another, enabling loop-in/loop-out or pass-through test strategies. As a result, test coverage can be achieved without requiring direct probing of every die, which simplifies external test access, supports parallel testing, and reduces the number of dedicated test pins needed per die.

The six-directional test access structure further enables rerouting in the event of a test path failure. If a die becomes inaccessible due to a fault or is temporarily disabled, adjacent dies can dynamically reconfigure the direction of test signal flow to bypass the affected path, ensuring continued test operation and system reliability.

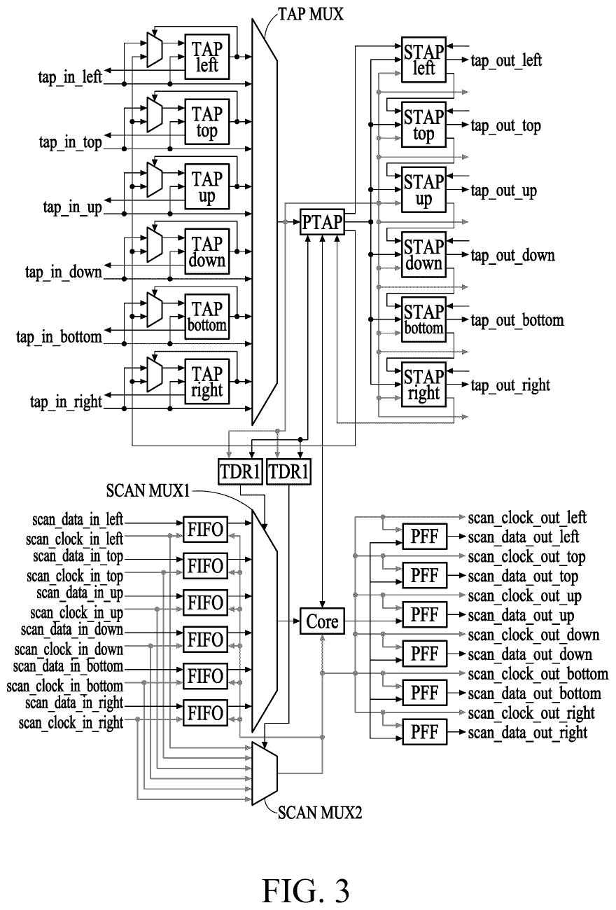

FIG. 3 is a schematic diagram illustrating an exemplary omnidirectional test access structure in a SoC or SoW in accordance with various embodiments of the present disclosure. As shown in FIG. 3, the example die includes six directional TAP controllers (e.g., TAP left, TAP top, TAP up, TAP down, TAP bottom, and TAP right), each configured to receive a corresponding TAP signal bundle (e.g., tap_in_left, tap_in_top, tap_in_up, tap_in_down, tap_in_bottom, and tap_in_right) from a neighboring die. Each TAP signal bundle includes five signals (that are, e.g., compliant with IEEE 1149.1), such as test data input (TDI), test mode select (TMS), test clock (TCK), test reset (TRST), and test data out (TDO). The outputs of the TAP controllers are routed to a TAP multiplexer (TAP MUX), which selects one input path based on a control signal (e.g., ptap_en).

The output of the TAP MUX is forwarded through a first test direction register (TDR1), which stores control bits for scan configuration and routing decisions. From TDR1, the TAP signal is routed to a first scan multiplexer (SCAN MUX1), which receives scan data and scan clock signals from six directions (e.g., scan_data_in_left, scan_data_in_top, scan_data_in_up, scan_data_in_down, scan_data_in_bottom, scan_data_in_right, and their corresponding scan_clock_in_* signals). SCAN MUX1 selects one of these directional input paths and forwards the selected scan data and clock signals to the core, which functions as the device under test (DUT). First-in-first-out (FIFO) buffers may be used to buffer and align scan input signals before entering SCAN MUX1.

The DUT core receives the selected scan data and clock signals, executes scan operations, and generates scan output responses. These responses include scan data and scan clock outputs directed toward six potential output directions (e.g., scan_data_out_left, scan_data_out_top, scan_data_out_up, scan_data_out_down, scan_data_out_bottom, scan_data_out_right and their respective scan_clock_out_* signals). These outputs are routed through a second scan multiplexer (SCAN MUX2), which selects the output direction. A second test direction register (TDR2), located between the TAP MUX and SCAN MUX2, may be used to store routing and timing control settings specific to the selected output direction. In some embodiments, the output signals may be buffered using pipeline flip-flops (PFFs) for re-timing and signal integrity improvement.

In addition to scan signal routing, the TAP output from the selected direction is transmitted through a corresponding STAP controller (e.g., STAP left, STAP top, STAP up, STAP down, STAP bottom, or STAP right). Each STAP controller is configured to generate a TAP signal bundle (e.g., tap_out_left, tap_out_top, tap_out_up, tap_out_down, tap_out_bottom, tap_out_right) for transmission to a neighboring die. These controllers also forward test control signals such as shift enable (SE), capture enable (CE), and update enable (UE) to enable scan operations (that are, e.g., in compliance with standards such as IEEE 1149.1 and IEEE 1838).

In one example of normal test operation, a TAP signal is received from the left direction via tap_in_left. The TAP controller decodes the incoming test instruction and asserts ptap_en for the left direction. The TAP MUX selects the left input path and forwards the selected signal through TDR1 to SCAN MUX1. The scan data and scan clock are selected from scan_data_in_left and scan_clock_in_left and sent to the core. After execution of the scan pattern, the scan output is routed through SCAN MUX2 and transmitted via scan_data_out_right and scan_clock_out_right. Simultaneously, the TAP output is sent through STAP right via tap_out_right, continuing the test sequence to the next die.

In a rerouting scenario, if the TAP left input becomes unavailable (e.g., due to a routing fault or inactive neighboring die), the system reconfigures the TDR1 to select another input path, such as tap_in_top. The TAP MUX updates its selection, and SCAN MUX1 receives input from scan_data_in_top and scan_clock_in_top. The scan results can then be sent to an alternative direction (e.g., down), routed through SCAN MUX2 and the corresponding STAP and output scan signals. The flexible reconfiguration of input/output directions via TDR1 and TDR2 enhances fault tolerance and routing flexibility.

In a roundtrip or loopback test mode, scan data and clock signals may be received from one direction (e.g., left) and returned through another direction (e.g., right) without entering the core scan chain. This mode can be implemented by configuring SCAN MUX1 and SCAN MUX2 to form a pass-through path, allowing interconnect diagnostics or interface verification without involving the DUT. TDR1 and TDR2 store the control bits needed to implement such loopback routing.

From the above description, the test access structure supports omnidirectional TAP and scan signal routing, flexible direction selection, rerouting, and roundtrip testing. The inclusion of six TAP/STAP controllers, two scan multiplexers, FIFOs and PFFs, and two direction registers (TDR1 and TDR2) enables scalable, programmable, and resilient test architectures suitable for large SoW systems, where each die may serve as both a test target and a conduit for neighboring dies.

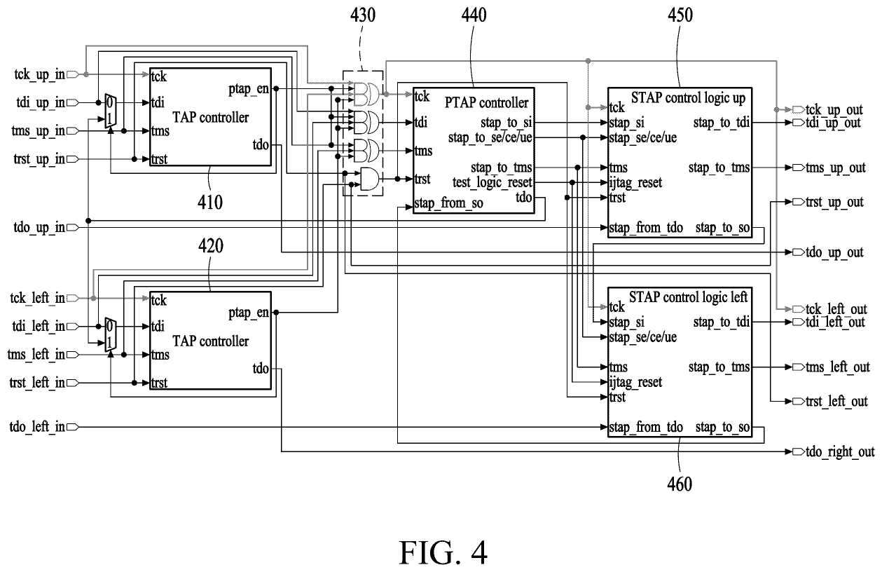

FIG. 4 is a schematic diagram illustrating a direction switching structure for two directions in accordance with various embodiments of the present disclosure. As shown in FIG. 4, the example die, e.g., in a SoC or chiplet architecture, includes a test access structure configured to operate in two directions (e.g., up and left). This switching structure includes a first TAP controller 410, a second TAP controller 420, a TAP multiplexer (TAP MUX) 430, a primary test access port (PTAP) main controller 440, a first STAP control logic 450 (up), and a second STAP control logic 460 (left).

The first TAP controller 410 receives a TAP signal bundle (e.g., TCK, TDI, TMS, TRST, TDO) from a neighboring die in the up direction. It decodes the signals and asserts a ptap_en signal when the up direction is active. Similarly, the second TAP controller 420 performs a similar function for the left direction, receiving and decoding the incoming TAP signals and asserting its ptap_en signal when the left direction is selected. These ptap_en signals are used as selection inputs for the TAP MUX 430.

The TAP MUX 430 is implemented using logic gates. The TCK, TDI, and TMS signals are routed through AND and OR logic based on the asserted ptap_en control signals. The TRST signal is routed such that each trst_out signal is directly connected to its corresponding trst_in input, thereby maintaining asynchronous reset capability. When either ptap_en signal is high, the corresponding TAP signal bundle is selected and forwarded to the PTAP main controller 440.

The PTAP main controller 440 receives the selected TAP signal bundle from the TAP MUX 430 and interprets the incoming test instructions. For example, it supports standard JTAG (IEEE 1149.1), IJTAG (IEEE 1687), and stacked-die (IEEE 1838) operations. The PTAP controller coordinates scan operations and drives TDI, TMS, and TDO to the selected STAP control logic. The TCK signal is routed directly from the TAP MUX to the STAP logic, while the TRST signal is delivered directly from the input source.

The first STAP control logic 450 (up) and second STAP control logic 460 (left) manage the outbound TAP signal bundles to their respective neighboring dies. Each STAP control logic receives internal test control signals from the PTAP controller 440 and outputs the bundled TAP signals (e.g., tap_out_up, tap_out_left).

In a normal test operation, the TAP signal bundle is received from the up direction through TAP controller 410. The ptap_en signal is asserted, causing TAP MUX 430 to forward the TDI, TMS, and TCK signals to PTAP controller 440. The PTAP processes the test instruction and triggers scan testing, while the processed TAP signals are routed through STAP control logic 460 and transmitted via tap_out_left to the next die.

In a rerouting scenario, if the up-direction TAP path is unavailable (e.g., due to a fault), the TAP controller 420 (left) becomes active. The system reconfigures the TAP MUX 430 to select the left input. PTAP controller 440 processes the incoming signals and sends the test response through STAP control logic 450 (up), effectively rerouting the test flow from left to up.

From the above description, the direction switching structure for two directions allows runtime reconfigurability using minimal hardware resources. For example, when a TAP signal is received from the up direction, the first TAP controller 410 asserts its ptap_en signal, enabling the TAP multiplexer 430 to forward the TDI, TMS, and TCK signals to the PTAP main controller 440. The PTAP interprets the instruction and initiates scan or boundary scan operations. The processed test signals are then routed through the second STAP controller logic 460 (left direction) to a neighboring die. This configuration supports bidirectional TAP access (e.g., up-to-left and left-to-up), and the logic-controlled TAP MUX along with independent STAP logics makes it scalable to additional directions. As a result, the architecture enables flexible test access in constrained or irregular die layouts and may be extended to support larger test networks in SoC or SoW implementations.

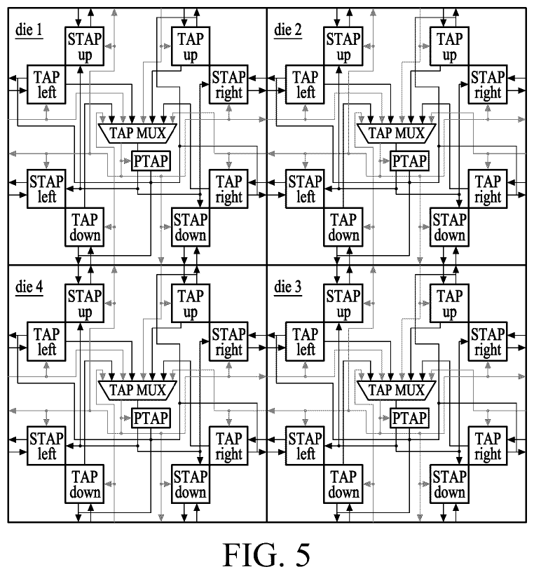

FIG. 5 is a schematic diagram illustrating an exemplary omnidirectional TAP structure in a SoW in accordance with various embodiments of the present disclosure. As shown in FIG. 5, the TAP access structure on SoW supports signal routing across a 2D grid of dies arranged in rows and columns, representing four dies (e.g., die1, die2, die3, die4) from a plurality of dies in the SoW, each configured to support directional TAP access in four directions (e.g., left, right, up, and down).

Each die includes four directional TAP controllers (e.g., TAP left, TAP right, TAP up, TAP down), a TAP multiplexer (TAP MUX), a primary test access port (PTAP) main controller, and four directional STAP control logics (e.g., STAP left, STAP right, STAP up, STAP down). Each TAP controller receives a TAP signal bundle from a neighboring die, including signals such as TCK, TDI, TMS, TRST, and TDO (e.g., compliant with IEEE 1149.1). When active, a TAP controller asserts a ptap_en signal to select that direction for test input.

The TAP MUX receives TAP signals from all four directions and selects one input set based on the ptap_en control signal. The selected TDI, TMS, and TCK signals are forwarded to the PTAP main controller for decoding, while TRST is routed asynchronously to maintain reliable reset handling.

The PTAP main controller processes the incoming TAP instruction and initiates appropriate scan or boundary scan operations. It then enables one of the STAP control logics, which drives a corresponding TAP signal bundle outward toward a neighboring die in the selected output direction (e.g., tap_out_right via STAP right). This TAP chaining enables flexible propagation of test instructions across the die grid in both row-wise and column-wise directions.

In a normal test scenario, a TAP signal may be received through tap_in_left. The corresponding TAP controller asserts ptap_en, enabling the TAP MUX to route the signal bundle to the PTAP controller. The test instruction is then processed and sent out through tap_out_right via STAP right, forming a left-to-right test path.

In a rerouting scenario, if a particular direction such as left is unavailable, the PTAP may dynamically select an alternate TAP input, such as tap_in_up, and redirect the output through a different STAP direction (e.g., tap_out_down), enabling test signal propagation to continue through a detour path. This reconfiguration enhances fault tolerance and improves test coverage.

The structure in FIG. 5 also supports roundtrip test operation. For example, test signals may be received from one direction (e.g., tap_in_down), internally looped back without engaging the scan logic, and returned via another direction (e.g., tap_out_up). This mode enables interconnect validation and localized diagnostics between neighboring dies on the SoW.

From the above description, the TAP access structure on SoW supports scalable, modular, and reconfigurable test integration. With omnidirectional TAP support and programmable routing paths, this architecture is well suited for wafer-scale integration, chiplet-based systems, and plug-and-play test environments requiring minimal external pin dependency.

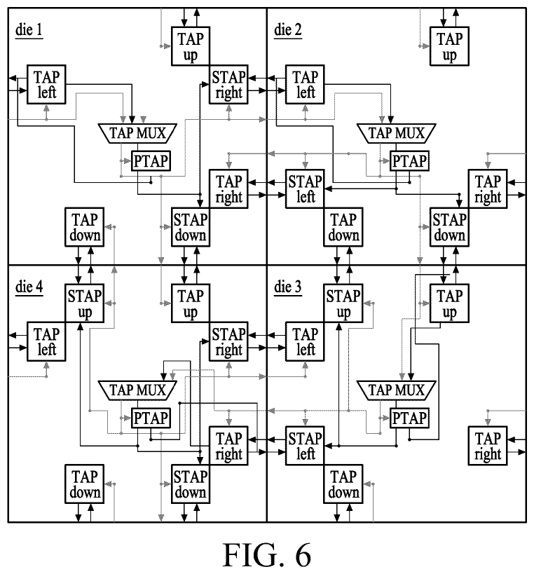

FIG. 6 is a schematic diagram illustrating another exemplary TAP access structure in a SoW in accordance with various embodiments of the present disclosure. The example test access architecture is an omnidirectional TAP structure on SoW and focuses on a selected TAP path through four of a plurality of dies arranged in an array of rows and columns (e.g., die1, die2, die3, die4). The structure supports inter-die test signal routing in a horizontal direction while retaining unused vertical interfaces (up and down) that may be activated in alternative test configurations.

As shown in FIG. 6, each die includes TAP controllers for left, right, up, and down directions, a TAP multiplexer (TAP MUX), a primary test access port (PTAP) main controller, and two STAP controllers for right and down directions. This configuration enables each die to receive TAP signals from one side and forward processed test signals to another side based on direction settings. The up and down TAP ports are available for rerouting scenarios but are inactive in the main propagation path shown.

In the illustrated test flow, TAP signals are received at die1 from the left direction via the TAP left controller. The signal bundle (e.g., TCK, TDI, TMS, and TRST) is selected by the TAP MUX, forwarded to the PTAP main controller for interpretation, and transmitted to die2 through the STAP right controller. This same operation continues through die2 and die3, forming a sequential TAP scan path from die1 to die4.

In a rerouting scenario, suppose the TAP left input of die2 is unavailable due to a defect or routing failure. The PTAP controller in die2 may detect the issue (e.g., by monitoring TCK activity) and reconfigure the test direction to use TAP up instead. Correspondingly, the STAP down controller in die1 is activated to transmit TAP signals vertically, preserving test continuity. This dynamic direction switching capability enables fault tolerance and ensures continued access across the SoW layout.

In a roundtrip test mode, the PTAP main controller may bypass the internal scan chain and instead return the received TAP signals back toward the originating die. For example, test signals received through TAP left in die1 may be redirected back via STAP left. This operation supports localized diagnostics and interconnect validation between neighboring dies without engaging the DUT scan chain, providing additional flexibility for debug and link verification.

From the above description, the directional TAP access structure is optimized for horizontal propagation while retaining support for rerouting and roundtrip configurations. The modular use of TAP and STAP blocks in selected directions allows each die to participate in the test chain with minimal hardware and the structure is scalable for implementation across larger SoW arrays.

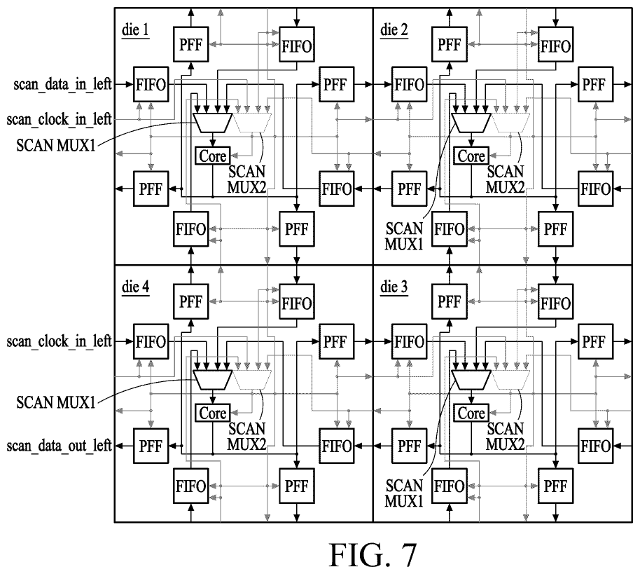

FIG. 7 is a schematic diagram illustrating an exemplary scan data access structure across multiple dies in a SoC or SoW in accordance with various embodiments of the present disclosure. As shown in FIG. 7, each example die (e.g., die1-die4) includes a core functioning as a DUT, a first scan multiplexer (SCAN MUX1), a second scan multiplexer (SCAN MUX2), four directional FIFOs, and four directional PFFs. The four FIFOs are respectively configured to receive scan input data and scan clock signals from neighboring dies in the left, right, up, and down directions, such as scan_data_in_left, scan_clock_in_left, scan_data_in_right, scan_clock_in_right, and so on. The output terminals of the FIFOs are coupled to SCAN MUX2, which selects one of the FIFO outputs as the scan input path for the DUT core.

The DUT core receives the selected scan data and scan clock signals from SCAN MUX2 and performs scan testing operations, including shifting scan patterns, capturing internal logic responses, and generating scan output data. The core's scan output data and clock signals are provided to SCAN MUX1, which selects one of four output directions. The output of SCAN MUX1 is routed to one of the directional PFFs (left, right, up, or down), each configured to buffer and re-time the outgoing signals. The output of each PFF is transmitted to a neighboring die as a scan output signal pair (e.g., scan_data_out_left, scan_clock_out_left, scan_data_out_right, scan_clock_out_right, etc.).

This configuration supports bidirectional scan signal routing and allows the scan data path to be dynamically configured during test operations. In one example of a normal scan operation, scan input data and clock signals (scan_data_in_left, scan_clock_in_left) are received through the left FIFO, routed via SCAN MUX2 to the DUT core, and the scan output (scan_data_out_right, scan_clock_out_right) is passed through SCAN MUX1 and the right-direction PFF to the next die, forming a left-to-right scan path.

In a rerouting scenario, if the left-direction FIFO becomes unavailable due to a fault or inactive neighbor, the scan input may instead be received from another direction, such as the top FIFO (scan_data_in_up, scan_clock_in_up). SCAN MUX2 is reconfigured to select the top input, and SCAN MUX1 may forward the output to the down-direction PFF, generating scan output signals such as scan_data_out_down and scan_clock_out_down. This enables vertical rerouting and improves fault resilience.

The two scan multiplexers, along with the directional FIFOs and PFFs, enable flexible and programmable scan path selection. Direction control for SCAN MUX1 and SCAN MUX2 may be derived from local configuration logic or test direction register (TDR) settings.

From the above description, the scan data access structure complements the omnidirectional TAP and STAP interfaces (e.g., those discussed in FIGS. 1-6) by providing an internal scan routing mechanism. This structure enables high test coverage, rerouting flexibility, and signal alignment across a grid of dies in a wafer-scale SoC or SoW system.

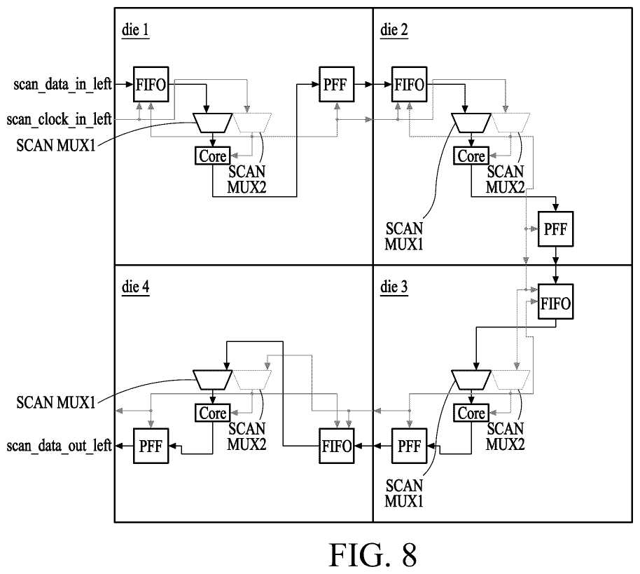

FIG. 8 is a schematic diagram illustrating another exemplary scan data access structure across multiple dies in a SoC or SoW in accordance with various embodiments of the present disclosure. As shown in FIG. 8, the example structure includes four of the plurality of dies (e.g., die1-die4) arranged in an array of rows and columns. Each die includes a scan data input (e.g., scan_data_in_left) and scan clock input (e.g., scan_clock_in_left) received from a neighboring die. Each die further includes a core serving as DUT, a first scan multiplexer (SCAN MUX1), a second scan multiplexer (SCAN MUX2), a FIFO buffer, and a PFF. The FIFO receives the scan input data and clock signals and forwards its output to SCAN MUX1, which selects the active scan data input. The selected scan data is then routed to the core.

The DUT core receives two inputs, e.g., the scan data from SCAN MUX1 and the scan clock from SCAN MUX2. The SCAN MUX2 selects one of the incoming scan clock sources, including the scan clock input received by the FIFO, and forwards the selected clock to the core. The core processes the scan data, executes shift and capture operations, and generates scan output data.

The scan output data from the core is routed to the PFF, which also receives the selected scan clock from SCAN MUX2. The PFF re-times and buffers the scan output before transmitting it to the next die in the scan path. For example, in die1, scan_data_in_left and scan_clock_in_left are received, processed through the FIFO, routed through SCAN MUX1 to the core, and output data is forwarded through the PFF to die2. This configured path continues through die2 and die3, and scan_data_out_left from die4 completes the test path.

In a rerouting scenario, if the scan input path (e.g., FIFO input) becomes unavailable due to a fault or an inactive neighbor, the multiplexer control logic may reconfigure SCAN MUX1 and SCAN MUX2 to select alternate input sources. This enables scan test continuity even in the presence of inter-die faults or connectivity issues.

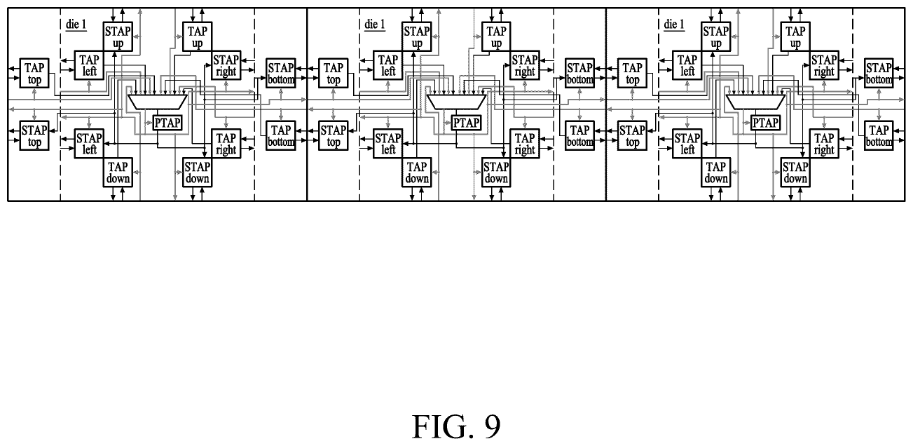

FIG. 9 is a schematic diagram illustrating another exemplary omnidirectional TAP access structure across multiple dies in a SoC or SoW in accordance with various embodiments of the present disclosure. As shown in FIG. 9, each example die includes directional TAP and STAP controllers in six directions: top, bottom, up, down, left, and right. These include TAP top, TAP bottom, TAP up, TAP down, TAP left, and a TAP right and corresponding STAP top, STAP bottom, STAP up, STAP down, STAP left, and a STAP right. The die also includes a TAP multiplexer (TAP MUX) and a primary test access port (PTAP) main controller.

Each directional TAP controller receives TAP input signals (e.g., TDI, TMS, TCK, and TRST) from a neighboring die. For example, TAP top receives data and clock signals from a die located directly above and provides the data to the TAP MUX, while the clock signal is used directly by other logic such as STAP controllers. Similarly, TAP bottom, TAP up, TAP down, TAP left, and TAP right receive input signals from their respective directions and provide their outputs to the TAP MUX.

The TAP MUX receives data inputs from the TAP controllers (e.g., TAP top, TAP left, TAP up, TAP down, TAP bottom, and TAP right), and selects one TAP input bundle based on a selection signal (e.g., ptap_en). The selected signals are routed to the PTAP main controller for decoding and execution of test instructions. The clock signals from the neighboring dies are distributed to the STAP blocks or routed alongside the selected TAP path for synchronization.

The PTAP main controller processes the selected TAP input, controls scan operations, and generates outgoing TAP instructions. These outputs are transmitted to the appropriate STAP controller depending on the selected output direction. For example, if the test is to be forwarded downwards, the PTAP sends the output to STAP bottom. For each STAP controller (e.g., STAP top, STAP up, STAP bottom, STAP down, STAP left, and STAP right), the corresponding clock signal is received either from the TAP MUX or directly from the neighboring die input.

The inclusion of TAP right and STAP right controllers allows expanded horizontal test routing. The TAP right and STAP right may be used for normal left-to-right propagation, while the TAP bottom and the STAP bottom can support additional vertical test routing, allowing signal flow between stacked dies. This approach reduces redundancy and provides a more area-efficient solution while preserving omnidirectional routing.

In one example, a TAP signal is received via TAP top of die1, routed through the TAP MUX to the PTAP controller, and forwarded to STAP bottom, which transmits the signal to the next die below. This continues down the SoW stack, supporting vertical test propagation.

In another example, if TAP top or STAP bottom is unavailable due to a fault, the PTAP controller may reroute the path through an alternative direction (e.g., from top to left or right), using the appropriate TAP and STAP pairs, including the TAP/STAP right if needed. The TAP MUX and PTAP main controller coordinate to enable such rerouting dynamically.

The structure also supports roundtrip or loopback testing. For example, a TAP signal received via TAP right may be processed by the PTAP controller and returned to the source die via STAP right or even through the STAP bottom, depending on the loopback configuration. This allows for interconnect testing and die-level link integrity diagnostics without engaging internal scan chains.

From the above description, the omnidirectional TAP access structure supports 3D directional routing (top, bottom, up, down, left, and right), test signal rerouting, and roundtrip test modes. The inclusion of TAP/STAP bottom controllers per die further enhances routing flexibility and redundancy in dense multi-die integration.

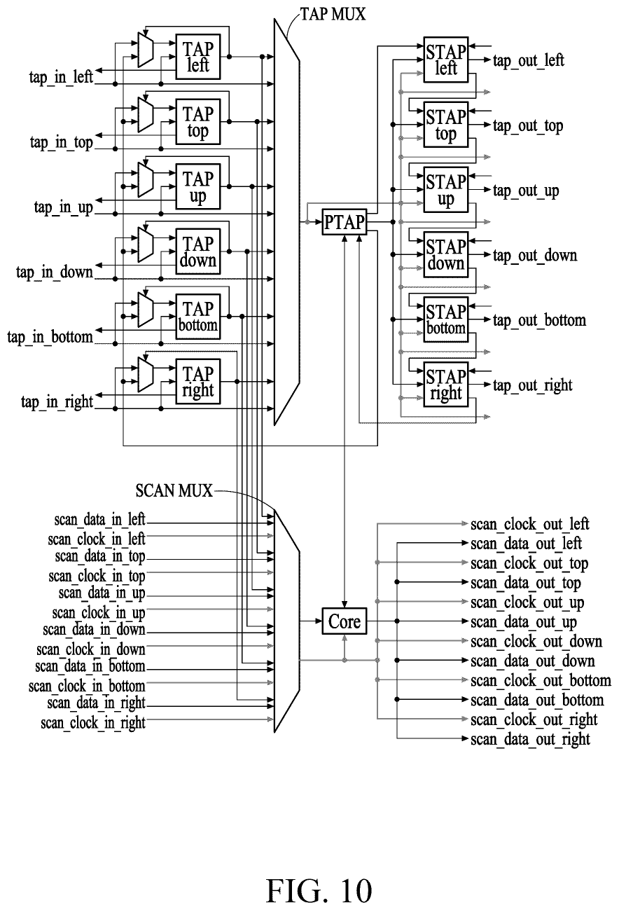

FIG. 10 is a schematic diagram illustrating another exemplary omnidirectional test access and scan signal routing structure within a die of a SoC or SoW in accordance with various embodiments of the present disclosure. As shown in FIG. 10, each example die includes six directional TAP controllers (e.g., TAP left, TAP right, TAP up, TAP down, TAP top, and TAP bottom), each receiving a TAP signal bundle (e.g., TDI, TMS, TCK, TRST) from a respective neighboring die. The outputs of these TAP controllers are routed to a TAP multiplexer (TAP MUX), which selects one input based on a configuration signal (e.g., ptap_en) or control logic.

The selected TAP signal bundle is forwarded to a primary test access port (PTAP) main controller, which interprets the test instructions and controls scan operations or boundary scan logic. The PTAP main controller also provides output test signals to six directional secondary TAP (STAP) controllers (e.g., STAP left, STAP right, STAP up, STAP down, STAP top, and STAP bottom). Each STAP controller forwards a corresponding TAP signal bundle (e.g., tap_out_left, tap_out_right, etc.) to a neighboring die in the designated direction. Clock signals may be routed directly from the TAP MUX to the STAP blocks for timing synchronization.

In addition to TAP routing, the die includes a scan multiplexer (SCAN MUX), which receives scan data and scan clock inputs from all six directions (e.g., scan_data_in_left, scan_data_in_right, scan_data_in_up, scan_data_in_down, scan_data_in_top, and scan_data_in_bottom) along with the corresponding clock signals. The SCAN MUX selects one of the directional input paths and forwards the selected scan data and scan clock to the core, which serves as the device under test (DUT).

The core receives the scan data and clock signals and executes the scan operations, such as shifting test patterns, capturing internal states, and generating scan output responses. The output scan data and clock signals (e.g., scan_data_out_left, scan_data_out_right, scan_data_out_up, scan_data_out_down, scan_data_out_top, and scan_data_out_bottom) are transmitted to neighboring dies via the corresponding directional links, enabling bidirectional and omnidirectional scan data flow. In this exemplary embodiment, because the test direction register (TDR) is omitted, the ptap_en signal is also used for direction control of the SCAN MUX. This means the same directional input is selected for both TAP and SCAN operations, simplifying signal coordination and reducing control overhead.

Compared to other embodiments, the structure is dispensed with components, such as FIFOs, PFFs, and ction registers (TDRs), offering a simplified implementation. This reduction in internal complexity may be advantageous in dense 3D SoW layouts where area and latency are constrained.

In one example of normal test operation, a TAP signal is received through the left direction via TAP left. The TAP MUX selects the left input, and the PTAP main controller processes the test command. Scan input data and clock signals are received through scan_data_in_left and scan_clock_in_left, respectively, and routed to the core through the SCAN MUX. After scan execution, the core outputs scan_data_out_right and scan_clock_out_right, which are transmitted to the next die in the right direction. The PTAP also forwards the TAP output bundle through STAP right to tap_out_right, completing the left-to-right test path.

In a rerouting scenario, if the left-side TAP input path is unavailable, the TAP MUX may select an alternate input such as TAP top, and the PTAP controller may reroute the processed signals to STAP bottom. Similarly, the SCAN MUX may switch to scan_data_in_top and output via scan_data_out_bottom. This supports rerouting and fault-resilient testing in highly integrated die arrays.

From the above description, the structure includes a six-directional TAP and scan access structure that enables omnidirectional signal flow, test signal rerouting, and flexible inter-die test path formation across SoC or SoW environments.

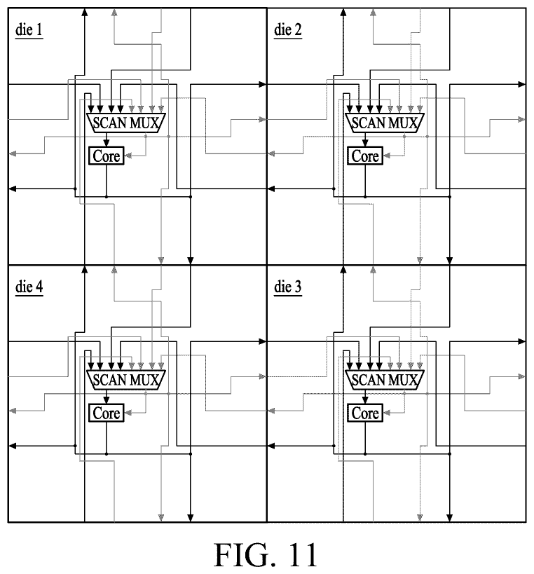

FIG. 11 is a schematic diagram illustrating another exemplary scan signal routing structure for a die in a SoC or SoW in accordance with various embodiments of the present disclosure. As shown in FIG. 11, each example die (e.g., die1-die4) includes a SCAN multiplexer (SCAN MUX), a core serving as a DUT, and directional scan data paths configured for communication with neighboring dies.

The SCAN MUX receives scan data and scan clock signals from multiple directions, including scan_data_in_left, scan_clock_in_left, scan_data_in_right, scan_clock_in_right, scan_data_in_up, scan_clock_in_up, scan_data_in_down, and scan_clock_in_down. Based on a selection control signal (e.g., derived from ptap_en or direction configuration logic), the SCAN MUX selects one of the directional input paths and forwards the selected scan data and clock signals to the core.

The core receives the scan data and clock from the SCAN MUX and performs scan operations such as shifting scan patterns, capturing test responses, and generating scan output. The scan output data and clock signals are then routed to the corresponding output direction: scan_data_out_left, scan_clock_out_left, scan_data_out_right, scan_clock_out_right, scan_data_out_up, scan_clock_out_up, scan_data_out_down, and scan_clock_out_down.

In this embodiment, each die includes an SCAN MUX and a DUT core, providing a directional scan routing mechanism. The architecture supports omnidirectional scan signal propagation across a grid of dies. Because no test direction register (TDR), the selection signal for the SCAN MUX may be shared with or derived from TAP direction control (e.g., ptap_en), which aligns TAP and SCAN paths for consistent routing.

For example, in a scan test flow from die1 to die4, scan data may be input from the left of die1, processed through the core, and output to the right. This pattern repeats through die2 and die3, forming a scan path from left to right across the die array. Similarly, vertical or diagonal routing can be achieved depending on the selected input/output paths.

From the above description, the structure of this embodiment enables rerouting capabilities. If a particular scan input direction becomes unavailable (e.g., scan_data_in_left), the SCAN MUX may switch to another direction (e.g., scan_data_in_up) to maintain scan continuity. Likewise, the scan output direction can be updated based on routing availability. Compared to other embodiments, this configuration omits FIFOs, PFFs, and TDRs, reducing internal complexity while maintaining flexible scan signal routing across SoC or SoW environments. This makes the architecture suitable for dense and area-constrained die integration.

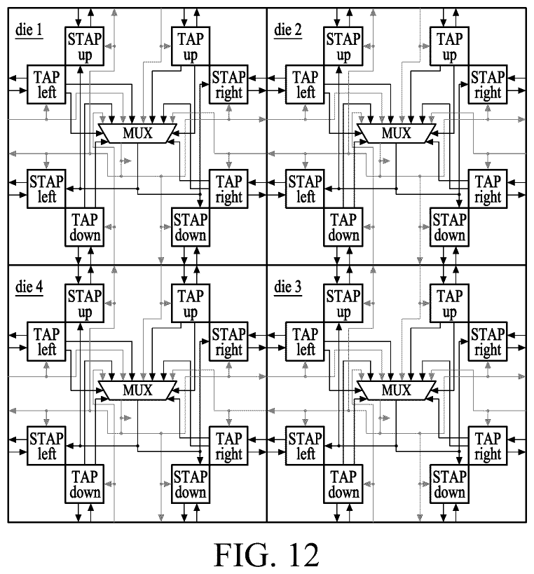

FIG. 12 is a schematic diagram illustrating another exemplary distributed TAP routing architecture across multiple dies in a SoC or SoW in accordance with various embodiments of the present disclosure. As shown in FIG. 12, each example die (e.g., die1-die4) includes four directional primary TAP controllers (PTAP left, PTAP right, PTAP up, PTAP down) and four corresponding STAP controllers (STAP left, STAP right, STAP up, STAP down). This configuration replaces the centralized PTAP main controller found in previous embodiments with independent PTAP controllers for each direction, enabling distributed and direction-specific test access.

Each PTAP controller receives a TAP signal bundle (e.g., TDI, TMS, TCK, TRST) from a neighboring die in a specific direction (e.g., tap_in_left for PTAP left). The PTAP controller decodes the test instruction and forwards it to a multiplexer (MUX). The MUX receives TAP signals from the four PTAP controllers and selects one based on a configuration signal, such as a direction selection control or ptap_en signal. The selected signals are routed to the appropriate STAP controller for outward propagation.

Each STAP controller transmits the processed TAP signals (e.g., TDI, TMS, TCK, TRST) to a neighboring die in the designated output direction. For example, STAP right receives TAP signals from the MUX and outputs them via tap_out_right to a neighboring die on the right. Each STAP controller may also receive a synchronized clock signal routed from the MUX to maintain timing consistency. In addition, the same STAP direction used for receiving may also be used to return the processed signal back to the originating die for roundtrip verification.

In one example of normal test operation, a TAP signal is received from the left direction at PTAP left. PTAP left decodes the signal, and the MUX selects this path and forwards the signals to STAP right. STAP right then transmits the signals to a neighboring die via tap_out_right, forming a left-to-right test path across the SoW.

In a rerouting scenario, if the left-direction TAP input becomes invalid due to a connectivity fault or inactive neighboring die, PTAP up may instead receive tap_in_up from the top die. The MUX selects this new input and routes it to STAP down, which then transmits the signal via tap_out_down to the lower die. This structure allows dynamic rerouting of test paths without requiring a centralized controller.

In a roundtrip test configuration, the PTAP controller may bypass the internal scan chain and route the received TAP signal back toward the source direction. For example, a signal received through tap_in_right at PTAP right may be processed and returned via STAP right to the same neighboring die. This roundtrip path enables localized link testing and verification of inter-die connections without entering the DUT scan logic.

From the above description, the distributed TAP routing structure supports flexible, direction-specific test access, rerouting, roundtrip testing, and inter-die TAP signal propagation across four directions. This approach provides higher adaptability for irregular or sparse SoW layouts and can improve fault tolerance by enabling decentralized routing control at each die.

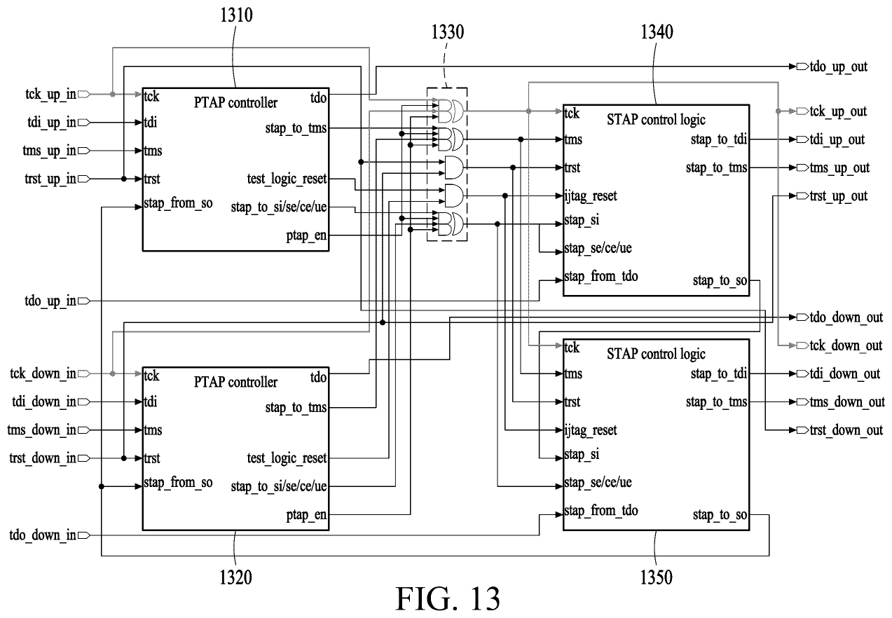

FIG. 13 is a schematic diagram illustrating an alternative two-directional TAP access structure in a die of a SoC or SoW in accordance with various embodiments of the present disclosure. As shown in FIG. 13, the example embodiment includes a first PTAP controller 1310, a second PTAP controller 1320, a TAP multiplexer (TAP MUX) 1330, a first STAP control logic 1340 (e.g., up direction), and a second STAP control logic 1350 (e.g., left direction). Unlike the centralized PTAP main controller used in the previous embodiments (e.g., those in FIGS. 4 and 9), the configuration of this embodiment adopts distributed PTAP controllers, one for each TAP input direction.

The first PTAP controller 1310 is configured to receive a TAP signal bundle (e.g., TDI, TMS, TCK, TRST) from a neighboring die in the up direction. Similarly, the second PTAP controller 1320 receives a corresponding TAP signal bundle from the down direction. Each PTAP controller decodes the input test signals, processes test commands, and generates outbound TAP signals. Each may include an internal test direction register (TDR) that determines the selected routing path.

The TAP multiplexer 1330 receives the processed outputs of both PTAP controllers 1310 and 1320. Based on configuration logic or ptap_en control signals, the TAP MUX selects one of the two processed TAP outputs and routes the signals to the selected STAP control logic, i.e., either STAP control logic 1340 (e.g., up direction) or STAP control logic 1350 (e.g., down direction).

Each STAP control logic 1340, 1350 is responsible for driving outbound TAP signals (e.g., tap_out_up or tap_out_down) to the neighboring die. These blocks transmit test instructions, scan commands, and synchronization signals based on the selected routing path. The TRST signals are directly connected from the respective trst_in inputs to the corresponding trst_out outputs. This configuration maintains proper asynchronous reset behavior across dies without introducing latency or logic interference in the STAP path.

In one example of test operation, a TAP signal is received from the up direction by PTAP controller 1310, processed locally and routed through TAP MUX 1330 to STAP control logic 1350. STAP control logic 1350 then transmits the test signals to the left-direction neighbor, completing an up-to-left test path. In another example, if the up path is unavailable, the test may be received from the down direction at PTAP controller 1320, processed, and sent out through STAP control logic 1340 toward the up direction, forming a down-to-up path.

This architecture also supports roundtrip test configurations. For example, the TAP signal received via PTAP controller 1310 (up direction) may be routed through TAP MUX 1330 and returned to the source die through STAP control logic 1340 (up direction), completing a loopback path. Likewise, a signal received from the down direction may be processed and returned via STAP left. This roundtrip capability allows inter-die link verification or signal integrity testing without requiring the test signal to traverse additional dies.

Compared to centralized PTAP configurations (e.g., those in FIGS. 4 and 9), the structure of this embodiment implements distributed PTAP controllers for local signal interpretation and places the TAP MUX downstream of the PTAPs, enabling selection between processed outputs rather than raw TAP inputs. This decentralized architecture reduces internal routing complexity and enhances modularity for directional test access in compact or minimal SoW environments.

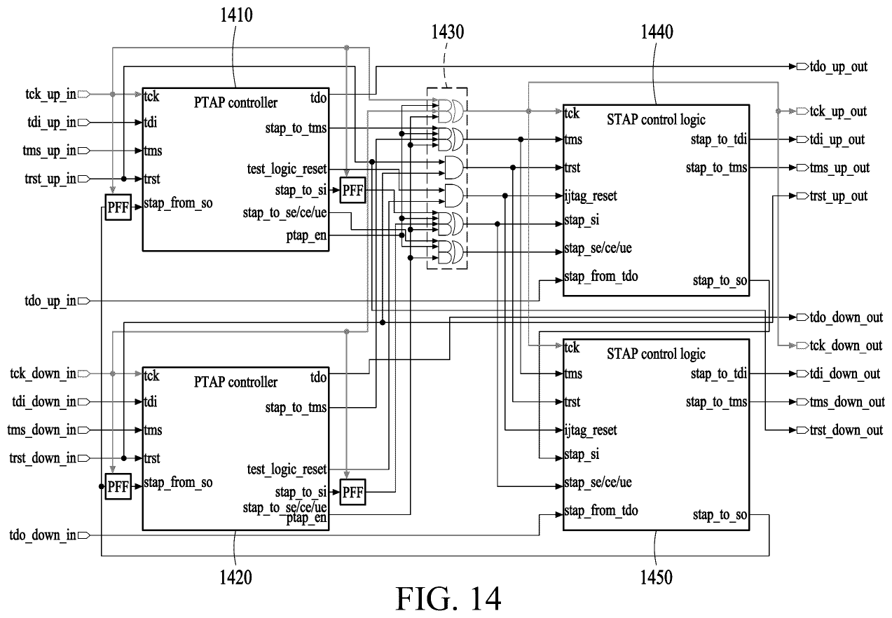

FIG. 14 is a schematic diagram illustrating another exemplary two-directional TAP switching structure including PFFs in a SoC or SoW in accordance with various embodiments of the present disclosure. The structure of this embodiment differs from those of the previous embodiment in that, as shown in FIG. 14, it further includes a plurality of PFFs to enhance signal integrity between distributed controllers and shared routing logic. For example, each die includes a first PTAP controller 1410, a second PTAP controller 1420, a TAP multiplexer (TAP MUX) 1430, a first STAP control logic (e.g., STAP up) 1440, a second STAP control logic (e.g., STAP down) 1450, and four PFFs configured for timing alignment.

The first and second PTAP controllers 1410, 1420 are configured to receive and interpret TAP signal bundles (e.g., TCK, TDI, TMS, TRST) from the up and down directions, respectively. These PTAP controllers 1410, 1420 operate independently and perform localized decoding and signal generation, eliminating the need for a centralized PTAP controller. Each PTAP controller 1410, 1420 generates outputs that include STAP signals (e.g., stap_to_si, stap_to_se/ce/ue) and a control signal (ptap_en) for selecting the downstream path.

The TAP MUX 1430 receives outputs from both PTAP controllers 1410, 1420 and selects one set of processed TAP signals (e.g., stap_to_si, stap_to_se/ce/ue, stap_to_tms, stap_to_tdi, etc.) to forward to one of the STAP control logic blocks 1440, 1450 based on the ptap_en control signal. Unlike configurations that multiplex raw TAP inputs, this architecture allows multiplexing of decoded and aligned test signals for downstream propagation.

Each STAP control logic 1440, 1450 (e.g., STAP up and STAP down) receives the selected TAP signal bundle from the TAP MUX 1430 and transmits it to a neighboring die in the corresponding direction (e.g., tap_out_up, tap_out_down). These STAP logics 1440, 1450 generate directional TAP outputs while receiving control and data signals from the selected PTAP controller 1410 or 1420. The TRST signals are directly connected from the respective trst_in inputs to the corresponding trst_out outputs bypassing the PTAP controllers, the TAP MUX, and/or STAP blocks. This direct routing preserves asynchronous reset behavior and avoids timing disruptions or interference in the scan path.

The first and second PFFs are placed between the STAP outputs (e.g., stap_from_so) and the inputs of the first and second PTAP controllers 1410, 1420. These PFFs buffer and re-time the TAP signal path before interpretation, helping to maintain synchronization and reduce noise from asynchronous or long routing paths.

The third and fourth PFFs are inserted between the outputs of the first and second PTAP controllers 1410, 1420 and the inputs of the TAP MUX 1430. These PFFs align the PTAP outputs with the shared MUX domain, maintaining signal integrity across domain boundaries and avoiding glitches or metastability issues.

In one example of normal test operation, a TAP signal is received from the down direction. The signal is re-timed by the second PFF, interpreted by the second PTAP controller 1420, and its output is buffered by the fourth PFF. The TAP MUX 1430 selects this output and routes it to the first STAP control logic 1440 (up), which then transmits the processed test signal to the neighboring die in the up direction.

In a rerouting example, if the down input becomes unavailable, the first PTAP controller 1410 may be activated to process input from the up direction. The first PFF re-times the incoming signal, the first PTAP controller 1410 decodes it, and the third PFF buffers its output before it is routed by the TAP MUX 1430 to the second STAP control logic 1450 (down), completing an up-to-down path.

From the above description, the structure of this embodiment is implemented as a refined TAP switching structure that includes four PFFs between the shared routing logic (TAP MUX 1430 and STAP controllers 1440, 1450) and each distributed PTAP controller 1410, 1420 to maintain signal integrity. The structure further ensures that the asynchronous TRST signals bypass internal logic and are connected directly from input to output. This approach supports robust bidirectional test access, rerouting, and modularity across multi-die SoC or SoW implementations.

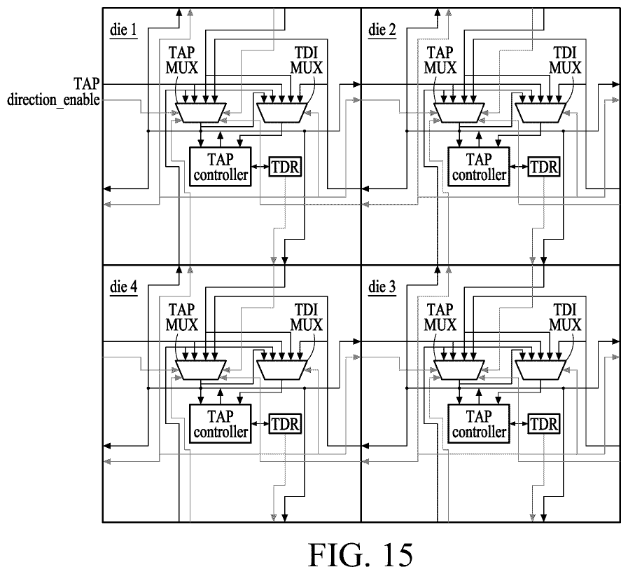

FIG. 15 is a schematic diagram illustrating another exemplary omnidirectional TAP access structure utilizing direction enable signals in accordance with various embodiments of the present disclosure. As shown in FIG. 15, the example die (e.g., die1-die4) includes four core components for directional TAP signal management, such as a TAP multiplexer (TAP MUX), a TAP controller, a test direction register (TDR), and a TDI multiplexer (TDI MUX). This structure reduces internal TAP and STAP block complexity by leveraging externally managed direction enable signals for test signal routing. Compared to previous embodiments, the structure of this embodiment omits FIFO buffers, PFF stages, and centralized PTAP controller logic, thereby simplifying internal circuitry while shifting more control to external interface protocols.

Each die (die1-die4) includes TAP input ports and direction_enable inputs for four directions (left, right, up, and down). The TAP MUX receives TAP signal bundles (e.g., TDI, TMS, TCK, TRST) and associated direction_enable inputs from all directions and selects one based on the asserted direction_enable signal. The selected TAP signal bundle is routed to the TAP controller.

The TAP controller manages scan test execution and direction control. It communicates with the TDR, which stores direction enable configuration in a format (e.g., one bit per direction). When a direction is selected, the TDR asserts the corresponding direction_enable output, which drives both the current die's TAP MUX and the neighboring die's TAP MUX to establish a consistent forward test path.

The TDI MUX receives five data inputs, e.g., one from the TAP MUX and four TDO signals from external TAP ports for each direction. Initially, the TDI MUX selects the output from TAP MUX. After the TAP controller finalizes a direction using the TDR, the TDI MUX updates its selection to forward the TDO signal corresponding to the selected direction. This switching completes the TAP path and enables dynamic TAP chaining.

During test initialization, all TRST signals across dies may be asserted globally. The TRST signal is deasserted only at the designated starting die, which then asserts a direction_enable line to activate a specific input direction. The TAP controller interprets the incoming test instruction, programs the TDR and asserts the direction_enable output for the next die in the sequence, allowing recursive propagation of test access across the die array.

In a rerouting scenario, if the TAP input from the intended direction is invalid or inactive, the TAP controller may apply a fallback policy. For example, if the left direction is unavailable, the TDR may be updated to assert the top direction_enable output instead. The TAP MUX then selects the top input path, and after test execution, the controller reasserts the enable for the next intended output direction (e.g., down), enabling rerouting.

A roundtrip or loopback mode may also be supported. In this case, a TAP signal entering from the top may be routed through the TAP MUX and returned through the same or opposite direction using the TDI MUX, without engaging internal scan chains. This loopback configuration is useful for verifying interconnect continuity between neighboring dies.

From the above description, the structure of this embodiment is implemented as an omnidirectional TAP structure based on direction enable control. This approach minimizes internal logic by eliminating centralized PTAPs, FIFOs, and PFFs, and supports flexible test path formation across SoC or SoW arrays. The trade-off lies in the need for external interfaces to manage direction_enable signaling, which shifts routing complexity from internal die logic to inter-die coordination mechanisms.

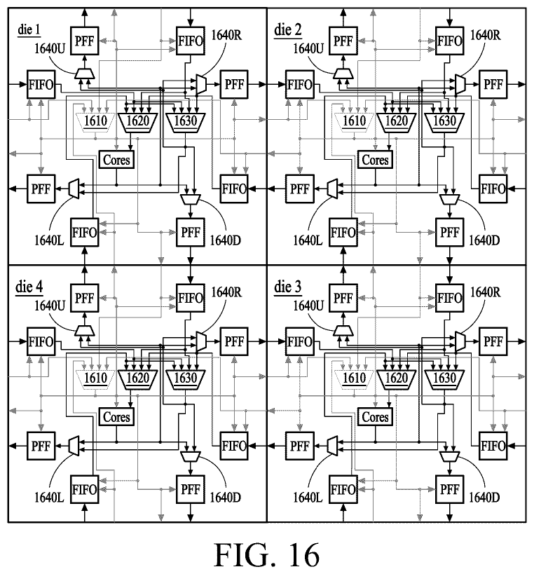

FIG. 16 is a schematic diagram illustrating another exemplary test access structure across multiple dies in a SoC or SoW in accordance with various embodiments of the present disclosure. As shown in FIG. 16, each example die (e.g., die1-die4) includes a clock multiplexer 1610, a first scan multiplexer 1620, a second scan multiplexer 1630, four directional FIFO buffers, four directional PFFs, a set of DUT cores, and four directional output multiplexers 1640L, 1640R, 1640U, 1640D.

Each FIFO receives TAP scan signals such as TDI, TMS, and TRST from a neighboring die in the left, right, up, or down direction and buffers the signals for timing alignment. The clock multiplexer 1610 receives multiple directional clock inputs such as TCK and selects one of them for distribution to the DUT cores and the PFFs.

The first scan multiplexer 1620 receives buffered TAP scan signals from the directional FIFOs and selects one source to deliver signals to the DUT cores. These signals are processed internally through scan chain logic or other test circuitry. At substantially the same time, the second scan multiplexer 1630 receives the same FIFO outputs and enables direct bypass to the output path if the DUT core is not engaged.

The output multiplexers 1607L to 1607D receive inputs from both the core 1606 and the second scan multiplexer 1630. Each output multiplexer 1607L to 1607D selects which data path to propagate toward the PFFs depending on the test configuration such as scan-through or loopback mode.

The PFFs re-time the output signals and drive them outward to adjacent dies, preserving signal integrity across inter-die interfaces. These elements ensure robust timing control especially under high-frequency operation or when long routing paths are present.

In a normal scan test scenario, TAP scan signals and clock signals are received via the left FIFO. The clock multiplexer 1610 selects the corresponding TCK, and the first scan multiplexer 1620 delivers the test signals to the DUT cores. After scan execution, the test output is sent to the right output multiplexer 1640R, which selects the core output for transmission through the right PFF, forming a left-to-right test path.

In a rerouting example, if the left FIFO fails or is inactive, the system may switch to the up-direction FIFO. The clock multiplexer 1610 selects the up-direction TCK, and the first scan multiplexer 1620 selects the TAP bundle from the up output multiplexer 1604U. The DUT processes the new input, and the down output multiplexer 1640D forwards the test result through PFF.

In a loopback or round-trip test mode, the scan data may be routed forward through a first path and returned along a reverse path using a configurable combination of scan multiplexers. For example, a scan data signal may enter die1, pass through the DUT cores of die2 and die3, and reach die4. Then, using the scan data selection logic (e.g., scan scan multiplexers), the return scan data path is reconfigured to propagate from die4 back to die3, die2, and finally return to die1. In this configuration, both scan MUXs are programmed to switch between forward and reverse paths, allowing the starting and ending points of the scan test to be in the same die. This round-trip scan routing enables inter-die continuity checks and supports diagnostic testing of multi-die signal paths without requiring external observation between intermediate stages.

From the above description, the directional test access structure of this embodiment incorporates flexible multiplexing, buffering, and rerouting logic. The modular design allows each die to operate independently in scan-in, scan-out, or bypass modes, providing robust and scalable support for multi-die test access in SoC or SoW environments.

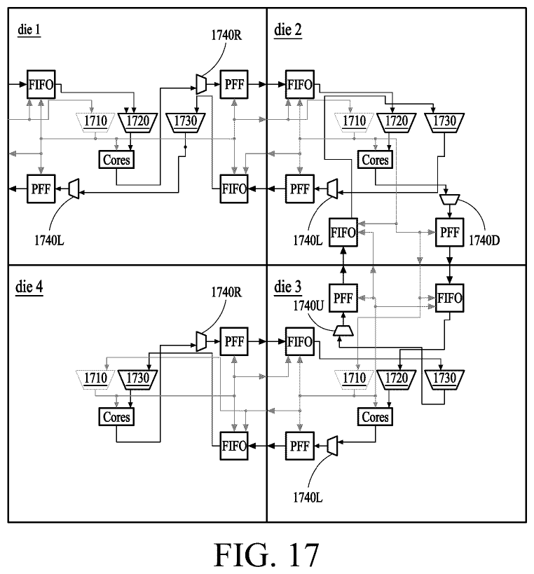

FIG. 17 is a schematic diagram illustrating a simplified scan data routing structure across multiple dies in a SoC or SoW in accordance with various embodiments of the present disclosure. As shown in FIG. 17, each example die (e.g., die1 through die4) includes a subset of directional scan components to support signal routing along the left and right directions, with selected dies supporting up or down routing. This embodiment also supports roundtrip test configurations and timing-aligned scan signal propagation.

Die1 includes a clock multiplexer 1710, a first scan multiplexer 1720, a second scan multiplexer 1730, two directional FIFOs including left and right FIFOs, two directional output multiplexers including a left output multiplexer 1740L and a right output multiplexer 1740R, and two PFFs including left and right PFFs. The clock multiplexer 1710 receives clock signals from the left and right directions and selects one as the scan clock for use throughout the die. The FIFOs receive scan data and clock inputs from their respective directions and forward buffered outputs to the first scan multiplexer 1720. The DUT core receives the selected scan input and clock, processes the test patterns, and sends output signals to the second scan multiplexer 1730. Based on test control configuration, the selected output signals are transmitted through either left or right multiplexer and driven to the neighboring die via left or right PFF.

Die2 includes a clock multiplexer 1710, a first scan multiplexer 1720, a second scan multiplexer 1730, left and down FIFOs, left and down PFFs, a down output multiplexer 1740D, and a left output multiplexer 1740L. This configuration allows Die2 to receive scan input from the left or down direction and propagate outputs either downward or to the left, enabling both vertical and horizontal scan handoff within the SoW.

Die3 includes a clock multiplexer 1710, a first scan multiplexer 1720, a second scan multiplexer 1730, up and left FIFOs, up and left PFFs, an up output multiplexer 1740U, and a left output multiplexer 1740L. This configuration allows Die3 to receive scan input from the up or left direction and to propagate scan output upward or leftward. The scan data and clock inputs are selected through multiplexers 1720 and 1710, respectively. The DUT core processes the scan pattern and the second scan multiplexer 1730 forwards the scan-out signals to the appropriate output multiplexer 1740U or 1740L, which then drives the selected output through the corresponding PFF to a neighboring die.

Die4 includes a clock multiplexer 1710, a scan multiplexer 1730, a right FIFO, a right PFF, and a right output multiplexer 1740R. This configuration allows Die4 to receive scan input data and clock signals from the right direction through the right FIFO. The clock multiplexer 1710 selects the scan clock, and the second scan multiplexer 1730 forwards scan output signals to the right output multiplexer 1740R, which transmits the signals to a neighboring die via the right PFF.

In an exemplary normal test operation, scan input data and clock signals are received via a FIFO (e.g., right FIFO in die4). The clock multiplexer 1710 selects the corresponding clock input, while the first scan multiplexer 1720 selects the scan input. These signals are routed to the DUT core, which processes the test pattern. The second scan multiplexer 1730 forwards the scan-out signals to the appropriate output multiplexer (e.g., left output multiplexer 1740L), which then drives the signals to the neighboring die via the corresponding PFF (e.g., left PFF).

In a rerouting scenario, if the input path from the default direction is unavailable, the system may dynamically reconfigure the clock multiplexer 1710 and the first scan multiplexer 1720 to select an alternative FIFO (e.g., up FIFO in die3 or left FIFO in die2). The DUT then processes the alternate input path, and the resulting scan data is forwarded via a different output direction using the corresponding multiplexer and PFF.

In a roundtrip or loopback test mode, the first scan multiplexer 1720 and the second scan multiplexer 1730 may be configured to bypass the core and route scan signals from an input FIFO (e.g., left FIFO) directly to an output multiplexer (e.g., right output multiplexer 1740R), enabling interconnect diagnostics. In such configurations, the scan input and output signals are aligned through the same die, reducing clock skew. This allows the scan output to be observed in the same clock cycle as the scan input, minimizing observation delay and enhancing signal integrity.

From the above description, the structure of this embodiment supports directional scan routing, rerouting in case of failure, and roundtrip configurations in a streamlined two-direction test setup. Selected dies support additional vertical routing to accommodate broader scan paths in an SoW mesh, while preserving compact signal alignment and timing consistency.

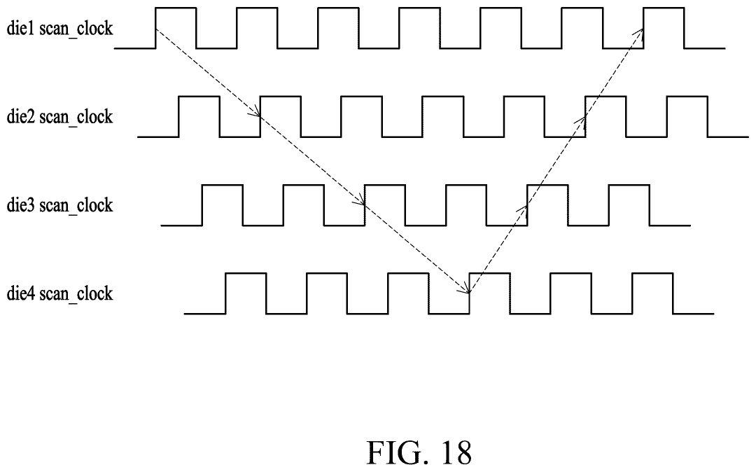

FIG. 18 is a timing diagram illustrating scan clock signal propagation in a roundtrip scan configuration within a SoW in accordance with various embodiments of the present disclosure. As shown in FIG. 18, the example timing profile captures both the forward and return scan paths across four dies (die1→die2→die3→die4 and die4→die3→die2→die1), providing a visualization of inter-die clock skew accumulation and reduction.

In the forward direction, the scan clock signal (e.g., TCK) propagates from die1 to die4. Each solid red arrow represents the rising edge of the scan clock as observed at die1, die2, die3, and die4 in sequence. The progressively delayed edge positions across the dies reflect the propagation delay introduced by the scan clock as it travels through interconnects, FIFOs, PFFs, and other timing elements.

In the return path, the scan clock travels back from die4 to die1. The dashed red arrows indicate the rising edges of the returning scan clock as seen at die4, die3, die2, and finally die1. Similar to the forward path, the returning clock edges accumulate delay. However, as the return path progresses closer to the originating die (die1), the timing skew between the outgoing and returning edges narrows.

This roundtrip configuration enables effective adjustment of observation timing for scan data. When scan data is sent out along the forward path and returned along the same or mirrored path, the delay introduced in the forward leg is offset by the reverse leg. This convergence results in reduced net clock skew at the point of return (die1), enabling the scan data output to be observed in the same cycle as the input was applied.

The timing diagram illustrates that in systems with long scan paths, especially in SoW architectures, clock delay becomes a dominant factor in determining scan timing. While external FIFOs can buffer and tolerate limited skew, there is a threshold beyond which timing errors may occur. The roundtrip route helps mitigate this issue by reusing the scan clock directionally, keeping the observation edge closely aligned with the launch edge.

As shown in FIG. 18, re-timing structures like clock multiplexers and PFFs further enhance timing precision by allowing localized clock selection and signal alignment. These components ensure that the scan data remains synchronized with the clock, even after traversing multiple dies.

From the above description, the timing profile underscores the benefits of roundtrip scan testing in large SoW arrays. It demonstrates how forward and return scan clock management can minimize skew, improve scan timing closure, and ensure robust signal observation across dies.

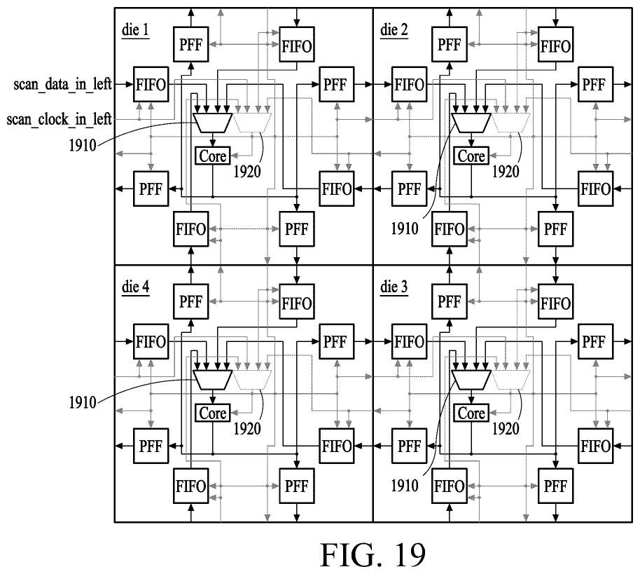

FIG. 19 is a schematic diagram illustrating another exemplary test access structure in a SoC or SoW in accordance with various embodiments of the present disclosure. As shown in FIG. 19, each example die (e.g., die1-die4) includes a clock multiplexer 1910, a scan multiplexer 1920, four directional FIFOs (left, right, up, and down), four directional PFFs (left, right, up, and down), and a core serving as a DUT.

Each FIFO receives scan data and control signals (e.g., TDI, TMS, TRST) from a neighboring die in a corresponding direction. For example, the left FIFO receives inputs from the left-side die, while the right, up, and down FIFOs receive from their respective directions. The outputs of the four FIFOs are routed to the scan multiplexer 1920, which selects one set of signals based on test direction configuration.

The clock multiplexer 1910 receives scan clock signals (e.g., TCK) from neighboring dies in the four directions and selects one as the internal scan clock for the die. The selected scan clock ensures synchronized operation across FIFOs, PFFs, and the DUT.

The outputs of the clock multiplexer 1910 and scan multiplexer 1920 are forwarded to the core. The core performs scan operations, such as capturing scan-in data, evaluating internal logic, and producing scan-out data. Depending on the test path configuration, the resulting scan output data is routed to one or more of the four output PFFs (left, right, up, and down).

Each PFF re-times the outgoing scan signals using the selected scan clock and transmits them to a neighboring die in the corresponding direction. These PFFs improve signal integrity and reduce timing skew across inter-die scan paths.

In one example of normal scan test operation, a die receives scan data and clock signals from the right-direction FIFO. The scan multiplexer 1920 selects the right input path, while the clock multiplexer 1910 selects the right-direction scan clock. The DUT executes scan operations using the received signals and outputs the scan result to the left-direction PFF, which transmits the re-timed data to the neighboring die on the left.

In a rerouting scenario, if the right FIFO is inactive or disconnected, the system may dynamically reconfigure the multiplexer selections to use the up FIFO and up clock input. The core 1930 then processes the new input, and the scan-out result is transmitted via the down-direction PFF, forming a rerouted vertical scan path.

From the above description, the omnidirectional scan access structure of this embodiment has an architecture with reconfigurable routing logic. Each die supports full directional input and output through the use of selectable multiplexers and dedicated re-timing logic, enabling flexible test path formation and fault-resilient signal routing across dense SoC or SoW environments.

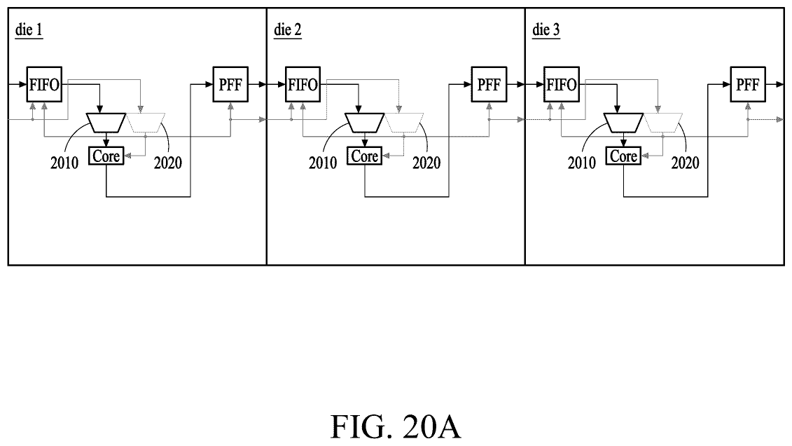

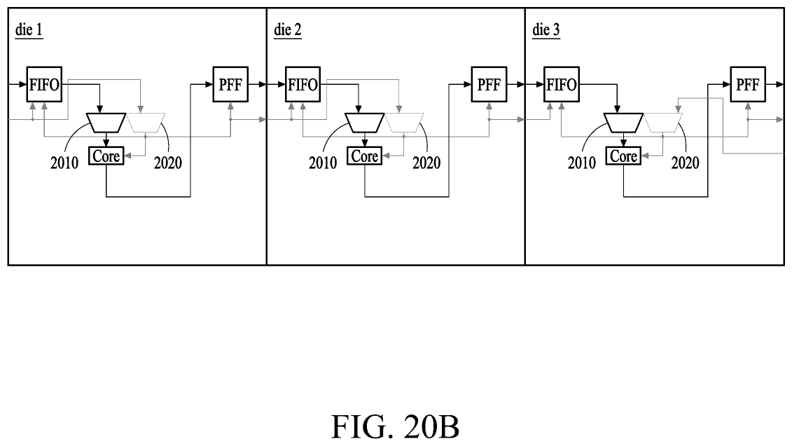

FIG. 20A is a schematic diagram illustrating an exemplary unidirectional scan access structure across multiple dies in a SoC or SoW in accordance with various embodiments of the present disclosure. In this exemplary embodiment, a plurality of horizontally arranged dies (e.g., die1 through die4) are configured to support scan signal propagation in a fixed direction (e.g., from left to right). This structure omits rerouting logic and supports unidirectional scan signal access.

Each die includes a FIFO, a scan multiplexer 2010, a clock multiplexer 2020, a core serving as a DUT and a PFF. The FIFO receives scan data and control signals (e.g., TDI, TMS, TRST) from a neighboring die in the left direction. The FIFO buffers these incoming signals to mitigate timing misalignment and maintain signal stability.

The scan multiplexer 2010 selects the buffered scan signal bundle and routes it to the DUT core. The clock multiplexer 2020 receives scan clock signals (e.g., TCK) from the left direction and forwards the selected clock signal to both the DUT and the output PFF.

The DUT core performs scan operations such as shift-in, capture, and shift-out procedures based on the selected data and clock inputs. The output scan signals from the DUT are routed to the PFF.

The PFF re-times the scan output using the scan clock and forwards the output scan scan signals to the next die in the right direction, thereby enabling seamless left-to-right scan flow across the SoW.

In one example of test operation, each die receives scan signals from the left direction and transmits the processed scan output to the right. Both data and clock directions are aligned from left to right across all dies, resulting in cumulative inter-die scan clock delay. This highlights the challenges of clock skew and setup/hold timing misalignment in such configurations.

From the above description, the structure of this embodiment provides a compact and efficient scan signal routing architecture ideal for use in predictable, single-direction scan paths. This design trades flexibility for simplicity and area savings, which may be preferable in constrained or uniform test environments.

FIG. 20B is a schematic diagram illustrating another exemplary unidirectional scan access structure across multiple dies in a SoC or SoW with reversed clock direction in accordance with various embodiments of the present disclosure. In this exemplary embodiment, a plurality of horizontally arranged dies (e.g., die1 through die4) are configured to propagate scan data from left to right, while scan clock signals are sourced in the opposite direction, from right to left.

As shown in FIG. 20B, each example die (die1-die4) includes a FIFO, a scan multiplexer 2010, a clock multiplexer 2020, a core serving as a DUT, and a PFF. The FIFO receives scan data and control signals (e.g., TDI, TMS, TRST) from the left direction and buffers the signals for improved timing alignment and signal integrity.

The scan multiplexer 2010 selects the buffered scan signal bundle from the FIFO and routes it to the DUT core. In contrast to the structure shown in FIG. 20A, the clock multiplexer 2020 receives scan clock signals (e.g., TCK) from the right direction and forwards the selected clock signal to both the DUT core and the output PFF.

The DUT core receives the scan and clock inputs and performs scan operations, including shift, capture, and scan-out procedures. The resulting scan output is forwarded to the PFF.

The PFF re-times the scan output using the scan clock and transmits the scan output signals to the right direction, completing the left-to-right data propagation path. The right-to-left clock direction offsets the data delay accumulated during left-to-right transmission, helping reduce timing skew.

In one example of test operation, each die receives scan signals from the left and scan clock signals from the right. This configuration improves scan clock alignment across dies and reduces maximum skew by compensating for scan data propagation delay with counter-propagating clock signals.

From the above description, the structure of this embodiment offers a unidirectional scan data path with improved timing alignment by reversing the clock source direction. This configuration enhances signal timing closure and test robustness across multiple dies on an SoW, while retaining a compact and area-efficient scan architecture

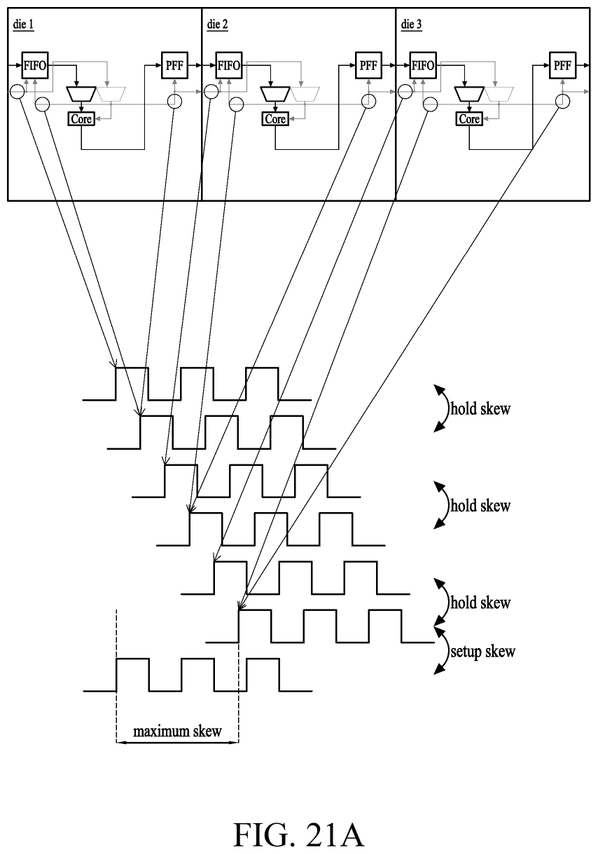

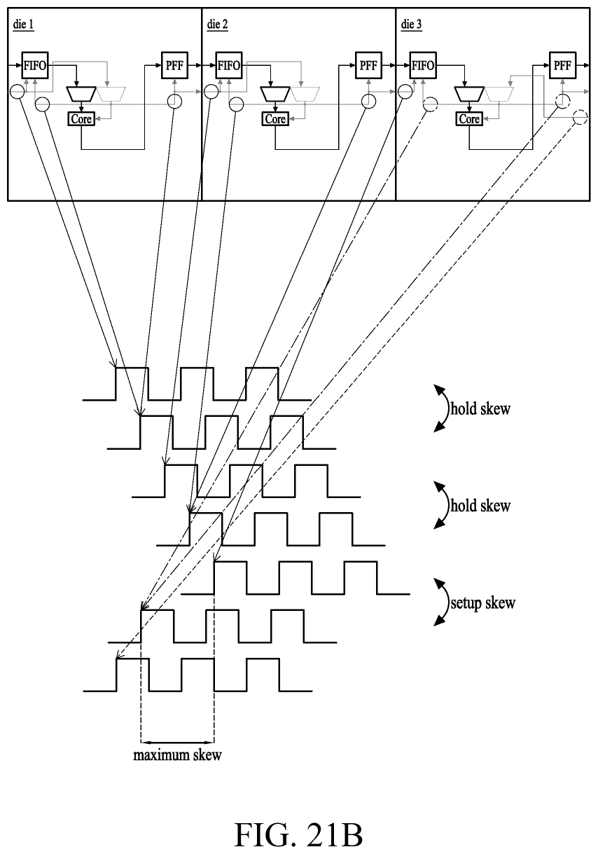

FIG. 21A is a timing diagram illustrating an example of inter-die scan clock skew accumulation in a SoW in accordance with various embodiments of the present disclosure. In this configuration, a plurality of dies (e.g., die1 through die4) are horizontally arranged on the SoW, and each die selects its scan clock (e.g., TCK) from its left input, aligning the clock propagation direction with the scan data flow direction, e.g., from left to right.

The rising edges of the scan clock signal are traced from the leftmost die (die1) to the rightmost die (die4). These edges are observed at test points within each die, such as the input of the FIFO, the output of the DUT core, and the input to the PFF. As the TCK signal propagates across dies, it accumulates delay due to inter-die interconnects, buffering delays, and internal timing paths, resulting in clock delay on SoW.

Because the clock signal is propagated in the same direction as the data, the cumulative skew increases across the scan chain. As shown in FIG. 21A, this causes the clock edges to become increasingly misaligned between dies. This leads to setup skew (the need for data to arrive earlier relative to the clock) and hold skew (the need to hold data stable after the clock edge). The maximum skew, shown at the bottom of the figure, represents the worst-case difference in rising edge alignment across the scan path.

Such a configuration, where both scan data and scan clock propagate left to right, is more susceptible to clock-data misalignment. To compensate, designers may need to allocate more FIFO depth or adopt conservative timing margins, which increases hardware cost and complexity.

FIG. 21B is a timing diagram illustrating another exemplary scan clock selection configuration in a SoW that reduces skew in accordance with various embodiments of the present disclosure. This example structure complements the configuration of FIG. 21A by showing the impact of sourcing the scan clock from the right input of each die, rather than the left. In such a configuration, scan data continues to propagate from left to right, while the scan clock (e.g., TCK) propagates from right to left across the chain of dies.

As shown in FIG. 21B, each die selects its scan clock from the right direction. This reversal of clock direction relative to data direction helps counteract the scan data delay accumulated during inter-die propagation. The rising edges of the TCK waveform are marked at key points within each die, including the input to the FIFO, the output of the DUT core, and the input to the PFF. These waveforms show improved alignment of clock edges across the dies compared to FIG. 21A.

Because the clock propagates against the direction of data flow, the delay introduced by the forward scan data path is partially compensated by the earlier arrival of the clock signal from the opposite direction. This results in reduced maximum skew across the SoW. As illustrated, the time gap between the first rising clock edge at die1 and the corresponding edge at die4 is narrower than in the configuration shown in FIG. 21A.

The setup skew and hold skew markers in FIG. 21B illustrate the timing window for which data must be valid and stable at each die. With improved clock alignment, these timing windows are more consistent and require fewer adjustments through retiming logic or FIFO depth. Consequently, systems implementing this reverse clock direction approach may benefit from reduced timing closure complexity and improved test timing robustness.

This configuration is particularly useful when implemented in scan architectures that allow separate selection of clock and data directions using clock multiplexers and data multiplexers. By decoupling the clock and data paths, and strategically selecting the clock source from the downstream side of the data flow, this approach helps mitigate worst-case inter-die timing skew in roundtrip or daisy-chained scan operations.

In summary, the waveform of FIG. 21B demonstrates that selecting the clock from the right input, i.e., opposite the direction of data flow, reduces the cumulative clock delay across dies and improves timing uniformity. This strategy enhances signal alignment and reduces the burden on downstream timing correction mechanisms.

From the above description, FIG. 21B thereby presents a complementary strategy to FIG. 21A, emphasizing how clock direction reversal can reduce inter-die skew and increase scan signal integrity in high-density SoW test systems.

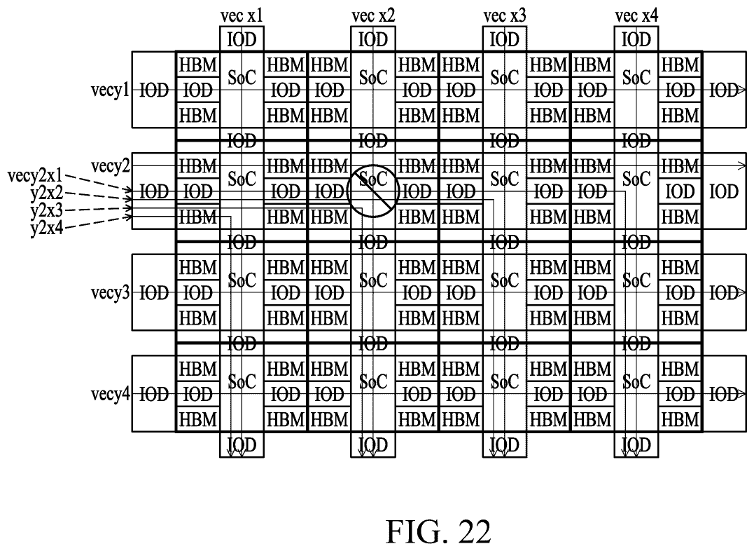

FIG. 22 is a schematic diagram illustrating an exemplary fault diagnosis system for identifying scan path faults in a SoW environment in accordance with various embodiments of the present disclosure. As shown in FIG. 22, the example structure includes a four-by-four array of semiconductor dies arranged in a grid on the SoW. The method leverages directional scan and TAP path testing across the array to localize faults based on test vector results.

The diagnosis method applies horizontal and vertical test vectors across the grid. Vectors y1, y2, y3, and y4 represent horizontal scan paths, while vectors x1, x2, x3, and x4 represent vertical scan paths. By analyzing the pass/fail results from these test vectors, fault locations can be systematically determined.

In one scenario, if a fault exists at the output of the SCAN MUX in SoC located at coordinate (X2, Y2), both vector x2 and vector y2 will fail, while all other vectors pass. This confirms the fault site. In another scenario, if only vector y2 fails and vector x2 passes, the fault is suspected to be at the input of the SCAN MUX along the horizontal path. To isolate the exact fault location, additional vectors such as y2x1, y2x2, y2x3, and y2x4 are applied. The first failing vector pinpoints the die containing the fault.

For example, if the results show that y2x1 passes but y2x2, y2x3, and y2x4 fail, the fault is identified at (X2, Y2). The path of y2x2 proceeds from (X1, Y2)→(X2, Y2)→(X2, Y3)→(X2, Y4), indicating that the failure originates at the second horizontal step.

Similarly, when a vertical vector such as x2 fails while y2 passes, the fault is suspected on the vertical path. Additional patterns x2y1, x2y2, x2y3, and x2y4 are applied, with each path taking a vertical segment followed by a left turn into a horizontal sequence. For example, x2y2 proceeds from (X2, Y1)→(X2, Y2)→(X3, Y2)→(X4, Y2). The first failing segment, such as x2y2, identifies (X2, Y2) as the fault location.

This fault identification method enables diagnosis not only of internal SCAN MUX errors but also of inter-die link faults across the SoW. By applying directionally bent scan vectors that combine horizontal and vertical segments, the system achieves fine-grained localization of scan path failures.

This embodiment may be implemented in combination with the architectures described in the sixth to twenty-first embodiments. Each SoC or die may include scan MUX, directional test access controllers, and associated logic to support the propagation and analysis of diagnostic vectors. This structure allows robust testing and fault isolation across large-scale SoW arrays.

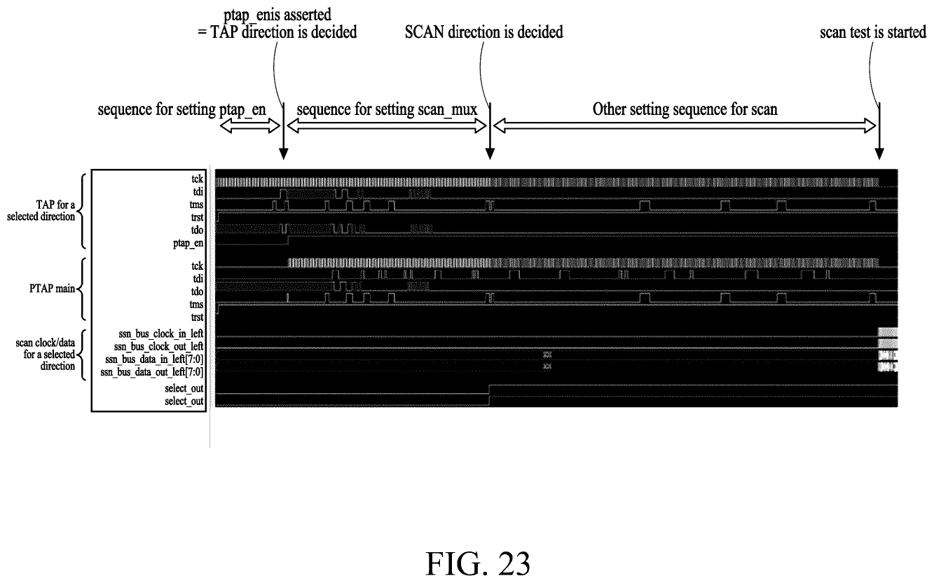

FIG. 23 is a timing diagram illustrating an exemplary initialization sequence for TAP and scan path selection in a SoC or SoW according to various embodiments of the present disclosure. In this exemplary embodiment, control and data signal transitions related to test path preparation are provided, including TAP direction setting, scan path selection, and signal initialization before scan testing starts. As shown in FIG. 23, the example timing diagram is divided into three sections. For example, the upper waveforms correspond to signals associated with a selected TAP direction (e.g., tck, tdi, tms, trst, tdo, ptap_en), while the middle waveforms correspond to signals associated with a centralized PTAP main controller (e.g., another set of tck, tdi, tdo, tms, trst). The lower waveforms correspond to scan bus activity (e.g., scan_bus_clock_in_left, scan_bus_clock_out_left, scan_bus_data_in_left[7:0], scan_bus_data_out_left[7:0]).

At the beginning of the timing sequence, all TAP and scan signals remain idle or in their initial states. The assertion of ptap_en, represented by its transition from low to high, indicates that a particular PTAP controller is activated for test routing. This transition corresponds to the selection of a TAP direction, initiating test access configuration in that direction.

Subsequently, after the ptap_en is asserted, the select_out signal is driven high. The interval between the assertion of ptap_en and the rising edge of select_out defines the sequence for configuring the scan multiplexer (i.e., scan_mux). The activation of select_out indicates that the scan direction has been successfully selected and the scan path is established. That is, this period indicates the phase in which the scan direction is decided.

At this time, the scan_bus_clock_in_left remains low, indicating that the scan clock is not being propagated. At substantially the same time, the scan_bus_data_in_left[7:0] may transition between high and low states to represent valid or toggling scan data input, depending on test controller behavior. These signals are stabilized before the test sequence begins. Once all relevant parameters are configured and ptap_en and select_out have both been asserted, scan test can begin. This is indicated as the arrow labeled “scan test is started.” At this stage, scan data and control signals begin to propagate through the selected scan direction and TAP path.

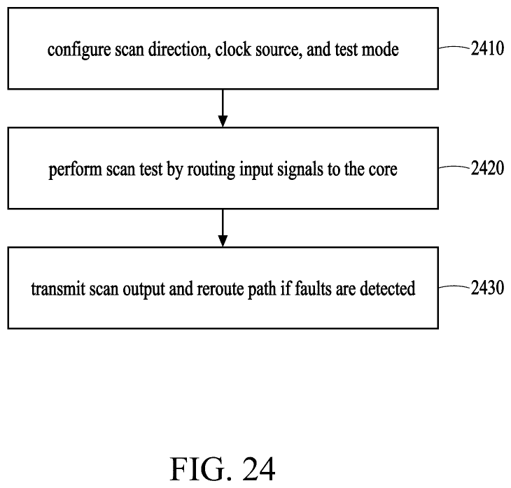

FIG. 24 is a flowchart illustrating exemplary operations of a method 2400 of in accordance with various embodiments of the present disclosure. The example method 2400 will now be described with further reference to FIGS. 1-23 for ease of understanding. It is understood that the method 2400 is applicable to structures other than those of FIGS. 1-23. Further, it is understood that additional operations can be provided before, during, and after the method 2400, and some of the operations described below can be replaced or eliminated, in an alternative embodiment of the method 2400.

In operation 2410, each die receives scan input signals from one or more neighboring dies. The scan input signals may include scan data and control signals (e.g., TDI, TMS, TRST) received via one of multiple directionally placed FIFOs (e.g., left, right, up, down), depending on the test configuration. Simultaneously, each die receives scan clock signals (e.g., TCK) from one or more neighboring dies via a clock multiplexer.

In operation 2420, a scan multiplexer selects one of the available input paths from the directional FIFOs and forwards the selected scan input signals to the core. Likewise, the clock multiplexer selects one clock signal for use by the core and PFF circuitry. In a normal test operation, the scan input and scan clock are selected from the same direction (e.g., both from the left), and the core performs a scan test using the received input.

In operation 2430, the core executes the scan operation using the selected data and clock input. This includes scan shift, capture, and output operations. The scan result from the core is forwarded to the selected output multiplexer, which then routes the signal to the appropriate directional PFF for output transmission.

In operation 2440, the output signal is re-timed by the PFF and transmitted to the neighboring die in the selected output direction, e.g., the direction opposite the scan input. In a rerouting scenario, when the default input path is unavailable (e.g., due to interconnect failure or inactive neighbor), the system reconfigures the input multiplexers to select an alternate FIFO and clock input from another direction (e.g., up or down instead of left or right). The scan multiplexer reroutes the new scan input signal to the core, and the clock multiplexer adjusts accordingly.

In operation 2450, the output multiplexer and PFF also reconfigure to transmit the scan output through a rerouted path, e.g., from vertical to horizontal or vice versa. This rerouted test configuration allows continued scan test operation in the presence of localized faults or inactive connections, ensuring test path continuity. In this manner, the method 2400 supports both standard and rerouted scan operations across neighboring dies in an SoC or SoW environment, maintaining robust scan test execution even in fault-prone interconnect scenarios.

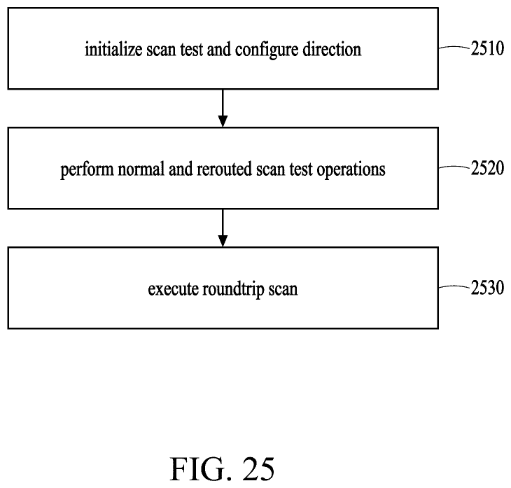

FIG. 25 is a flowchart illustrating exemplary operations of a method 2500 in accordance with various embodiments of the present disclosure. The example method 2500 will now be described with further reference to FIGS. 1-23 for ease of understanding. It is understood that the method 2500 is applicable to structures other than those of FIGS. 1-23. Further, it is understood that additional operations can be provided before, during, and after the method 2500, and some of the operations described below can be replaced or eliminated, in an alternative embodiment of the method 2500.

In operation 2510, scan test initialization is performed. Each die receives scan test configuration, including scan direction settings, scan clock selection, and activation of one or more FIFOs or scan multiplexers. Scan data and control signals (e.g., TDI, TMS, TRST) and scan clock signals (e.g., TCK) are received from a neighboring die in the configured direction, buffered if necessary, and routed to the core of each die.

In operation 2520, a normal scan test operation is performed. The scan multiplexer routes the selected input scan data and clock to the core, which executes scan shift-in, capture, and shift-out operations. The processed scan output is forwarded to a neighboring die via a selected output direction, using a PFF for signal re-timing if present.

In operation 2530, a rerouting operation is performed in response to a fault or unavailable input direction. The scan and/or clock multiplexers are dynamically reconfigured to select an alternate input direction (e.g., top, bottom, left, or right) from which scan data and clock signals are received. The core processes the new input and transmits the scan output to a different neighboring die via a rerouted output direction.

In operation 2540, a roundtrip or loopback scan test operation is performed. Scan data and clock signals are received from a first direction (e.g., left), passed through scan and clock multiplexers, and returned through an opposite or same direction (e.g., right) without entering the core scan chain. This operation enables interconnect diagnostics and clock alignment observation between neighboring dies without using the DUT core.

From the above description, the method 2500 supports normal, rerouting, and roundtrip scan test operations in a unified scan architecture. The configuration of multiplexers, FIFOs, PFFs, and the ability to dynamically switch signal paths allows flexible and scalable test signal routing across SoW or SoC designs.

In an embodiment, a semiconductor system comprises a plurality of dies arranged on a substrate and each including a core, a first multiplexer, a clock multiplexer, and a plurality of output circuits. The core performs scan test operations. The first multiplexer receives scan data and control signals from at least one neighboring die and provides the scan data and control signals to the core. The clock multiplexer receives scan clock signals from at least one neighboring die and provides a selected scan clock signal to the core. Each output circuit includes an output multiplexer and a pipeline flip-flop and transmits scan data and control signals from the core (CORE) to a neighboring die. The output multiplexer is coupled to the core. The pipeline flip-flop is coupled to the output multiplexer.

In another embodiment, a method for scan signal rerouting in a semiconductor system that includes a plurality of dies arranged on a substrate comprises: receiving, at a first die, scan data and control signals from at least one neighboring die; receiving, at the first die, scan clock signals from the at least one neighboring die; selecting, at the first die, one of the scan data and control signals as an input to a core using a first multiplexer; selecting, at the first die, one of the scan clock signals as a clock input to the core using a clock multiplexer; performing scan test operations in the core using the selected scan data, control, and clock signals; generating scan output signals from the core; selecting, based on test configuration, one of a plurality of scan output paths from the core; and rerouting the scan output signals to an alternative output direction when a default output path is unavailable.

In another embodiment, a method of operating a semiconductor system that includes a plurality of dies arranged on a substrate, where each die includes a core, a scan multiplexer, a clock multiplexer, and a plurality of scan input and output paths, comprises: receiving a scan input signal and a scan clock signal at a first die of the plurality of dies from a neighboring die in a first direction; selecting, via a scan multiplexer and a clock multiplexer of the first die, the scan input signal and the scan clock signal, respectively; forwarding the selected scan input signal and the selected scan clock signal across a sequence of intermediate dies in a forward scan direction; routing the scan input signal and the scan clock signal to a target die located at an end of the sequence; reversing the direction of signal propagation from the target die; returning the scan input signal and the scan clock signal from the target die to the first die in a reverse scan direction; and observing, at the first die, a scan output signal in a same scan clock cycle in which the scan input signal was received, thereby reducing clock skew in the roundtrip scan path.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor system comprising:
a plurality of dies arranged on a substrate, each die including:
a core configured to perform scan test operations;
a first multiplexer configured to receive scan data and control signals from at least one neighboring die and to provide the scan data and control signals to the core;
a clock multiplexer configured to receive scan clock signals from at least one neighboring die and to provide a selected scan clock signal to the core; and
a plurality of output circuits, each output circuit including:
an output multiplexer coupled to the core, and
a pipeline flip-flop (PFF) coupled to the output multiplexer, wherein each output circuit is configured to transmit scan data and control signals from the core to a neighboring die.

2. The semiconductor system of claim 1, wherein:
each die further includes a plurality of first-in-first-out (FIFO) circuits; and
each FIFO circuit is configured to receive scan data and control signals from a corresponding neighboring die in a respective direction, to buffer the received signals to align timing, and to forward the buffered signals to the first multiplexer for scan input selection.

3. The semiconductor system of claim 2, wherein:
each die further includes a plurality of PFFs; and
each PFF is configured to receive scan data and control signals from a corresponding output circuit, to re-time the outgoing signals based on the selected scan clock, and to transmit the re-timed signals to a neighboring die in the selected direction to ensure signal integrity across the inter-die boundary.

4. The semiconductor system of claim 3, wherein each output circuit includes a directional output multiplexer and configured to select either the scan output signals from the core or bypassed input signals from the first multiplexer and to route the selected signals to a corresponding pipeline flip-flop for transmission to a neighboring die.

5. The semiconductor system of claim 4, wherein each die further includes a centralized primary test access port (PTAP) controller configured to receive a scan signal bundle from the first multiplexer, to decode the test instructions, manage test timing and data propagation, and to control the operation of the first multiplexer, the clock multiplexer, and the output multiplexers based on a test configuration.

6. The semiconductor system of claim 5, wherein the PTAP controller is configured to detect a loss of scan input from a default input direction and to dynamically reconfigure the first multiplexer and the clock multiplexer to select an alternate FIFO input path and corresponding clock input from a different direction, thereby rerouting the scan test path around the faulty region to maintain test continuity.

7. The semiconductor system of claim 6, wherein:
each die further includes a test direction register (TDR) coupled to the PTAP controller; and
the TDR is configured to store scan direction settings indicating the selected input and output directions for scan signal routing and to provide control signals to the first and second multiplexers to implement the selected scan path configuration.

8. The semiconductor system of claim 7, wherein:
the PTAP controller is further configured to operate in a roundtrip scan mode; and
scan data signals received from a FIFO in a first direction are routed through the core and returned to the same neighboring die via the opposite direction output circuit.

9. The semiconductor system of claim 8, wherein, in the roundtrip scan mode:
the core is configured to transmit a scan output signal during a same scan clock cycle in which the scan input signal is received by the core; and
the roundtrip scan path is configured to reduce scan clock skew and to enable timing calibration during scan testing.

10. The semiconductor system of claim 9, wherein:
the PTAP controller is further configured to perform fault diagnosis based on scan test responses received from the scan path;
the PTAP controller is further configured to identify a potential fault site at a location where scan vectors applied in both horizontal and vertical directions produce a failure response; and
the PTAP controller is further configured to generate and apply additional scan vectors that traverse the suspected coordinates in different paths to isolate a fault at the scan input or output of a scan multiplexer.

11. A method for scan signal rerouting in a semiconductor system including a plurality of dies arranged on a substrate, the method comprising:
receiving, at a first die, scan data and control signals from at least one neighboring die;
receiving, at the first die, scan clock signals from the at least one neighboring die;
selecting, at the first die, one of the scan data and control signals as an input to a core using a first multiplexer;
selecting, at the first die, one of the scan clock signals as a clock input to the core using a clock multiplexer;
performing scan test operations in the core using the selected scan data, control, and clock signals;
generating scan output signals from the core;
selecting, based on test configuration, one of a plurality of scan output paths from the core; and
rerouting the scan output signals to an alternative output direction when a default output path is unavailable.

12. The method of claim 11, further comprising:
detecting a scan path failure at a first FIFO or associated multiplexer by monitoring signal integrity or timing behavior; and
selecting an alternate scan input direction by reconfiguring a test direction register to switch to a second FIFO and corresponding output flip-flop.

13. The method of claim 11, further comprising:
bypassing the core of a die during rerouting by forwarding scan input signals from a selected FIFO directly to a corresponding output multiplexer; and
transmitting the scan signals to a neighboring die without passing through the core.

14. The method of claim 11, further comprising:
reconfiguring the test direction register to reroute scan signals between horizontal and vertical paths; and
selecting a scan clock input independently of the scan data direction using a clock multiplexer to reduce clock skew during rerouted scan operations.

15. The method of claim 11, further comprising:
updating the scan direction based on stored rerouting configuration or scan path availability; and
applying a rerouting policy that prioritizes known-good directions when test results indicate scan path degradation.

16. The method of claim 11, further comprising initiating a roundtrip scan mode in response to a failed scan path, wherein scan signals are redirected through a rerouted path and returned to the originating die for loopback verification, enabling interconnect diagnostics without engaging all internal scan chains.

17. The method of claim 11, further comprising:
performing fault diagnosis based on test response patterns from multiple scan directions;
identifying a fault coordinate in a die array; and
generating additional test patterns along alternate rerouted scan paths to isolate the specific scan input or output where the fault occurs.

18. A method of operating a semiconductor system including a plurality of dies arranged on a substrate, each die including a core, a scan multiplexer, a clock multiplexer, and a plurality of scan input and output paths, the method comprising:
receiving a scan input signal and a scan clock signal at a first die of the plurality of dies from a neighboring die in a first direction;
selecting, via a scan multiplexer and a clock multiplexer of the first die, the scan input signal and the scan clock signal, respectively;
forwarding the selected scan input signal and the selected scan clock signal across a sequence of intermediate dies in a forward scan direction;
routing the scan input signal and the scan clock signal to a target die located at an end of the sequence;
reversing the direction of signal propagation from the target die;
returning the scan input signal and the scan clock signal from the target die to the first die in a reverse scan direction; and
observing, at the first die, a scan output signal in a same scan clock cycle in which the scan input signal was received, thereby reducing clock skew in the roundtrip scan path.

19. The method of claim 18, wherein:
each intermediate die forwards the scan input signal and the scan clock signal from a scan input path to a scan output path without processing the signals through the core; and
the scan multiplexer and the clock multiplexer of each die are configured to support signal selection from multiple directions to enable reversal of the scan path for roundtrip propagation.

20. The method of claim 18, further comprising comparing, at the first die, the scan output signal to an expected response to detect scan path faults, wherein alignment of the scan output timing with the scan input timing compensates for clock propagation delay and enables observation and fault localization along the forward and reverse paths.
